(19) United States
(12) Patent Application Publication
(10) Pub. No.: US 2022/0289631 A1
(43) Pub. Date: Sep. 15, 2022

(54) BERYLLIUM OXIDE PEDESTALS

(71) Applicant: MATERION CORPORATION, Mayfield Heights, OH (US)

(72) Inventors: Larry T. SMITH, Mayfield Heights, OH (US); Fritz C. GRENSING, Mayfield Heights, OH (US); Zan ASLETT, Mayfield Heights, OH (US); Robert E. KUSNER, Mayfield Heights, OH (US); Jeffrey R. CAMPBELL, Mayfield Heights, OH (US); Aaron B. SAYER, Mayfield Heights, OH (US); Kyung H. CHUNG, Mayfield Heights, OH (US); Gordon V. LU, Mayfield Heights, OH (US)

(73) Assignee: MATERION CORPORATION, Mayfield Heights, OH (US)

(21) Appl. No.: 17/634,160

(22) PCT Filed: Aug. 13, 2020
(86) PCT No.: PCT/US2020/046045

§ 371 Date: Feb. 9, 2022

Related U.S. Application Data
(60) Provisional application No. 62/887,282, filed on Aug. 15, 2019.

(51) Int. Cl. C04B 35/08; C04B 35/628; C04B 41/45; C04B 41/52

(52) U.S. Cl. CPC C04B 35/08; C04B 35/62894; C04B 41/4547; C04B 41/52; C04B 2235/3206; C04B 2235/3418; C04B 2235/3217; C04B 2235/3865; C04B 2235/9607; C04B 2235/963

(57) ABSTRACT

A base plate containing a having a top and a bottom and comprising a beryllium oxide composition containing at least 95 wt % beryllium oxide and optionally fluorine/fluoride ion. The base plate demonstrates a clamping pressure of at least 133 kPa at a temperature of at least 600° C. and a bulk resistivity greater than 1×10⁵ ohm-m at 800° C.

### CROSS-REFERENCE TO RELATED APPLICATION

This application claims priority to U.S. Provisional Patent Application No. 62/887,282, filed Aug. 15, 2019, the entirety of which is incorporated herein by reference.

### FIELD

The present disclosure relates to ceramic pedestals for high temperature applications. In particular, the disclosure relates to pedestals comprising beryllium oxide for use in semiconductor production processes.

### BACKGROUND

In many high temperature substrate processing applications, the substrate is treated, e.g., etched, coated, cleaned, and/or has its surface energy activated in a high temperature processing chamber. To perform the treatment, process gases are introduced into the process chambers and then energized to achieve a plasma state. The energizing may be done by applying an RF voltage to an electrode, e.g., a cathode, and electrically grounding an anode to form a capacitive field in the process chamber. The substrate is then treated by the plasma generated within the process chamber to etch or deposit material thereon.

During this process, the substrate must be supported (and held in place). In many cases, ceramic pedestals are employed to achieve this goal. In some instances electrostatic chuck assemblies are employed (as a part of the pedestals) to hold in place the substrate. Other support mechanisms are known as well, e.g., mechanical and vacuum. The electrostatic chucks often comprise an electrode covered by a dielectric. When the electrode is electrically charged, an opposing electrostatic charge accumulates in the substrate and the resultant electrostatic force holds the substrate onto the electrostatic chuck. Once the substrate is firmly held on the chuck, the plasma treatment proceeds.

Some known plasma processes are often performed at somewhat high temperatures and in highly erosive gases. For example, processes for etching copper or platinum are conducted at temperatures of from 250° C. to 600° C., compared to temperatures of 100° C. to 200° C. for etching aluminum. These temperatures and erosive gases thermally degrade the materials used to fabricate the chucks. Conventional ceramic pedestals have employed various oxides, nitrides, and alloys, e.g., aluminum nitride, aluminum oxide, silicon dioxide, silicon carbide, silicon nitride, sapphire, zirconia, or graphite or anodized metals, as the main component. In some cases, these requirements can be met by conventional ceramic materials, e.g., aluminum oxide or aluminum nitride.

As technology advances however, higher substrate treatment operating conditions (temperatures), e.g., temperatures above 650° C., above 750° C., or above 800° C., are desired. Unfortunately, conventional ceramic pedestal materials have been found to suffer from structural problems, e.g., decomposition, thermal and/or mechanical degradation, powdering, and delamination, at these higher temperatures.

In addition, conventional ceramic pedestals have been found to demonstrate inconsistent temperature uniformity across the pedestal plate surface during operation—perhaps due to the inherent properties of aluminum nitride, silicon dioxide, or graphite. This, in turn, leads to problematic inconsistencies in the treatment applied to the semiconductor wafer. Attempts have been made to improve temperature uniformity in conventional pedestal plates. But these attempts include much more complex heating configurations and control mechanisms, e.g., an increased number of heating zones and thermocouples, which add cost and uncertainty to the formation process.

Also, conventional non-beryllium pedestals have struggled to provide sufficient chucking force (clamping pressure) necessary to retain the wafers in place, especially at higher temperatures. Conventional pedestals also suffer from problems relating to micro-fractures, surface powdering, (thermal) decomposition, and reduced effusivity at elevated temperatures. Even at moderate temperatures, the conventional pedestals have problems with unchucking time, perhaps due to high capacitance.

Further, many conventional pedestals employ layered structures that rely upon an adhesive-type bonding, e.g., using a braze material, or lamination via diffusion bonding to secure the metallic conductor within multiple (ceramic) layers. Such laminate structures, however, repeatedly suffer from structural problems and delamination that often a result from the stresses of the high temperature operations.

Also, it may be desirable to rapidly cool the substrate in order to maintain the substrate in a narrow range of temperatures or to clean the pedestal, the substrate, or the chamber. However, temperature fluctuations occur in high power plasmas due to variations in the coupling of RF energy and plasma ion densities across the substrate. These temperature fluctuations can cause rapid increases or decreases in the temperature of the substrate, which require stabilization. Thus, it is desirable to have a pedestal that requires little or no cooling during cleaning, e.g., one that can be cleaned at operating temperatures and/or with little or no cleaning cycle time, which advantageously improves process efficiency (by reducing/eliminating downtime).

Even in view of the conventional pedestal technology, the need exists for an improved pedestal assembly that has improved performance, e.g., reduced decomposition, reduced thermal, micro-fracture reduction, and/or mechanical degradation, improved temperature uniformity, and/or superior clamping pressure, especially at higher temperatures, e.g., above 650° C., while demonstrating no inter-layer delamination.

### BRIEF DESCRIPTION OF THE FIGURES

FIG. 1 is graph showing thermal diffusivity of Examples and Comparative Examples plotted over a temperature range from 0° C. to 900° C.

FIG. 2 is graph showing specific heat of Examples and Comparative Examples plotted over a temperature range from 0° C. to 900° C.

FIG. 3 is graph showing thermal conductivity of Examples and Comparative Examples plotted over a temperature range from 0° C. to 900° C.

FIG. 4 is graph showing effusivity of Examples and Comparative Examples plotted over a temperature range from 0° C. to 850° C.

FIG. 5 is graph showing bulk resistivity of Examples and Comparative Examples plotted over a temperature range from 0° C. to 850° C.

FIG. 6 is graph showing bulk resistivity of Examples and Comparative Examples plotted over a temperature range from 0° C. to 850° C.

### SUMMARY

In some embodiments, the disclosure relates to a pedestal assembly comprising: a shaft and a base plate, the shaft contains a first beryllium oxide composition containing beryllium oxide and (from 1 ppb to 1000 ppm or from 10 ppb to 800 ppm) fluorine/fluoride ion, and the base plate contains a second beryllium oxide composition containing at least 95 wt % beryllium oxide and optionally fluorine/fluoride ion. The base plate demonstrates a clamping pressure of at least 133 kPa and/or and a bulk resistivity greater than 1×10⁵ ohm-m at 800° C. The first beryllium oxide composition may comprise more fluorine/fluoride ion than the second beryllium oxide composition and may be processed to achieve the fluorine/fluoride ion concentration. The first beryllium oxide composition may further comprise less than 50 wt % magnesium oxide and less than 50 wt % ppm silicon dioxide and/or from 1 ppb to 50 wt % ppm alumina; from 1 ppb to 10000 ppm sulfites; and/or from 1 ppb to 1 wt % ppm boron, barium, sulfur, or lithium, or combinations thereof including oxides, alloys, composites, or allotropes, or combinations thereof. The first beryllium oxide composition ma have an average grain boundaries greater than 0.1 micron and/or an average grain size less than 100 microns. The second beryllium oxide composition may further comprise from 1 ppb to 10 wt % ppm magnesium oxide and from 1 ppb to 10 wt % ppm silicon dioxide and/or from 1 ppb to 10 wt % ppm magnesium trisilicate and/or from 1 ppb to 1 wt % lithia. The first beryllium oxide composition may comprise more magnesium oxide and/or magnesium trisilicate than the second beryllium composition. The first beryllium oxide composition ma comprise less than 75 wt % aluminum nitride and/or the second beryllium oxide composition may comprise less than 5 wt % aluminum nitride. The first beryllium oxide composition may have a conductivity less than 300 W/m-K at room temperature and/or a theoretical density ranging from 90% to 100%, and the second beryllium oxide composition may have a conductivity less than 400 W/m-K at room temperature. The base plate may demonstrate a temperature variance of less than ±3%, when heated to a temperature over 700° C., and/or a bulk resistivity greater than 1×10⁴ ohm-m at 800° C., and/or a corrosion loss of less than 0.016 wt %, and/or may have a dielectric constant less than 20, and/or a surface hardness of at least 50 Rockwell on a 45N scale, and/or a coefficient of thermal expansion ranging from 5 to 15 throughout the base plate, and/or a minimum transverse measurement across the base plate is at least 100 mm, and/or a flatness with a camber of less than 50 microns across a distance of 300 mm. The base plate may further comprise a heating element encapsulated in the base plate and/or a mesa, optionally having a height greater than 1 micron. The base plate may contain fewer than 2 layer laminations and/or no discrete layers. The shaft may comprise a stub portion having a similar coefficient of thermal expansion.

The disclosure also relates to a base plate having a top and a bottom and comprising a beryllium oxide composition, containing at least 95 wt % beryllium oxide and optionally fluorine/fluoride ion. The base plate may demonstrate a clamping pressure of at least 133 kPa at a temperature of at least 600° C. and/or a decomposition change of less than 1 wt % at temperatures greater than 1600° C., and/or a temperature variance of less than ±3%, when heated to a temperature over 700° C.; and/or a bulk resistivity greater than 1×10⁸; and/or corrosion loss of less than 0.016 wt %; and/or a dielectric constant less than 20; and/or a surface hardness of at least 50 Rockwell on a 45N scale; and/or a bulk resistivity greater than 1×10⁵ ohm-m at 800° C., and/or a coefficient of thermal expansion ranging from 5 to 15 throughout the base plate (the coefficient of thermal expansion may vary from top-to-bottom by less than 25%), and/or a cleaning cycle time less than 2 hours, and/or a temperature variance of less than ±3%. The base plate may comprise a beryllium oxide composition comprising from 1 ppb to 10 wt % ppm, e.g., 1 ppm to 5 wt %, magnesium oxide and from 1 ppb to 10 wt % ppm, e.g., 1 ppm to 5 wt %, silicon dioxide and/or from 1 ppb to 10 wt % ppm, e.g., 1 ppm to 5 wt %, magnesium trisilicate. The base plate may contain no discrete layers and may have a decreasing top-to-bottom thermal conductivity gradient; and/or a decreasing top-to-bottom resistivity gradient; and/or a decreasing top-to-bottom purity gradient; and/or a decreasing top-to-bottom theoretical density gradient; and/or an increasing top-to-bottom dielectric constant gradient. The base plate may further comprise a heating element optionally comprising niobium and/or platinum, optionally a coiled and/or crimped heating element and/or an antenna. The top purity may be at least 0.4% greater than the bottom purity.

The disclosure also relates to a base plate having a top and a bottom and comprising a beryllium oxide composition, wherein the base plate has: a decreasing top-to-bottom thermal conductivity gradient; and/or a decreasing top-to-bottom resistivity gradient; and/or a decreasing top-to-bottom purity gradient; and/or a decreasing top-to-bottom theoretical density gradient; and/or an increasing top-to-bottom dielectric constant gradient. The base plate may have a top thermal conductivity ranges from 125 to 400 W/mK and a bottom thermal conductivity ranges from 146 W/mK to 218 W/mK, when measured at room temperature; and/or a top thermal conductivity ranges from 25 W/mK to 105 W/mK and a bottom thermal conductivity ranges from 1 W/mK to 21 W/mK, when measured at 800° C., with the top thermal conductivity optionally being at least 6% greater than the bottom thermal conductivity, when measured at room temperature; and/or the top thermal conductivity optionally being at least 6% greater than the bottom thermal conductivity when measured at 800° C. A top purity may range from 99.0 to 99.9 and a bottom purity may range from 95.0 to 99.5. The top purity may be at least 0.4% greater than the bottom purity. A top theoretical density may range from 93% to 100% and a bottom theoretical density may range from 93% to 100%. The top theoretical density may be at least 0.5% greater than the bottom theoretical density. A top dielectric constant may range from 1 to 20 and a bottom dielectric constant may range from 1 to 20. The base plate may contain no discrete layers. The base plate may demonstrate the aforementioned clamping pressure, temperature variance, and corrosion loss.

The disclosure also relates to a shaft for a pedestal assembly comprising a beryllium oxide composition containing beryllium oxide and (10 ppb to 800 ppm) fluorine/fluoride ion. The beryllium oxide composition has average grain boundaries greater than 0.1 micron, and/or an amorphous grain structure, and/or an average grain size less than 100 microns, and/or may demonstrate a thermal conductivity less than 300 W/m-K at room temperature, and/or a theoretical density ranging from 90 to 100. The shaft may demonstrate a top thermal conductivity ranges from 146 W/mK to 218 W/mK and a bottom thermal conductivity ranges from 1 W/mK to 218 W/mK, when measured at room temperature; and/or a top thermal conductivity ranges from 1 W/mK to 21 W/mK and a bottom thermal conductivity ranges from 1 W/mK to 21 W/mK, when measured at 800° C., and the top theoretical density may be at least 0.5% greater than the bottom theoretical density. The beryllium oxide composition may comprise less than 75 wt % aluminum nitride. The first beryllium oxide composition may comprise from 1 ppb to 1000 ppm fluorine/fluoride ion, and/or less than 50 wt % magnesium oxide, and/or less than 50 wt % ppm silicon dioxide, and/or from 1 ppb to 50 wt % ppm alumina, and/or from 1 ppb to 10000 ppm sulfites, and/or from 1 ppb to 1 wt % ppm boron, barium, sulfur, or lithium, or combinations thereof including oxides, alloys, composites, or allotropes, or combinations thereof.

The disclosure also relates to a pedestal assembly comprising: the shaft of any of aforementioned embodiments, and a base plate containing multiple layers bonded with one another optionally with a braze material, and an optional printed heating element.

The disclosure also relates to a base plate having a top and a bottom and comprising a ceramic composition, wherein the base plate demonstrates: a clamping pressure of at least 133 kPa; a temperature variance of less than ±3%, when heated to a temperature over 700° C.; and/or a bulk resistivity greater than 1×10⁸ at 800° C.; and/or a corrosion loss of less than 0.016 wt %; and/or a dielectric constant less than 20; and/or a surface hardness of at least 50 Rockwell on a 45N scale; and/or a coefficient of thermal expansion ranging from 5 to 15 throughout the base plate.

The disclosure also relates to a process for making a base plate, the process comprising the steps of: providing a first BeO powder and a third BeO powder; forming a second powder from the first and third powders; forming a first (bottom) region from the first powder; forming a second (middle) region from the second powder; forming a third (top) region from the third powder to form a base plate precursor, wherein the second region is disposed between the first and third regions; optionally co-mingling the base plate precursor to knit the powders, optionally placing a heating element in one of the regions and/or crimping of terminals, optionally cold forming the base plate precursor, and firing the base plate precursor to form the base plate. The first and third (and second) powders may comprise different grades of raw BeO.

The disclosure also relates to a process for making a pedestal shaft, comprising processing a beryllium oxide composition to achieve a fluorine/fluoride ion concentration ranging from 1 ppb to 1000 ppm fluorine/fluoride ion.

The disclosure also relates to a process for cleaning a contaminated pedestal assembly, comprising: providing the pedestal assembly and a wafer with the wafer disposed atop the pedestal assembly; heating the wafer to a temperature above 600° C.; cooling the wafer by less than 100° C. to a cooled temperature (or no cooling at all); cleaning the plate at the cooled temperature; optionally re-heating the wafer to 600° C.; wherein a cleaning cycle time from the cooling step to the reheating step is less than 2 hours. The cleaning cycle time may range from 0 to 10 minutes.

### DETAILED DESCRIPTION

As noted above, conventional pedestal assemblies are often used to support and hold in place semiconductor substrates during treatment, e.g., chemical vapor deposition, etching, etc. Typical ceramic pedestals have employed various oxides, nitrides, and alloys, e.g., aluminum nitride, aluminum oxide, silicon dioxide, or graphite, as the main component. And these ceramic materials can meet the needs of treatment methods at medium-high temperatures, e.g., temperatures below 650° C. or below 600° C. However, as technology advances, higher substrate treatment operating temperatures, are desired e.g., temperatures above 650° C. or even above 800° C. Unfortunately, conventional ceramic pedestal materials have been found to suffer from structural problems, e.g., decomposition, thermal and/or mechanical degradation, and delamination at these higher temperatures. In addition, conventional pedestal materials are known to have insufficient bulk resistivity. In some cases, the poor resistivities lead to insufficient chucking/clamping force necessary to retain the wafers in place, especially at higher temperatures.

Further, conventional ceramic pedestals have been found to demonstrate inconsistent temperature uniformity across the pedestal plate surface, which leads to problematic inconsistencies in the treatment applied to the semiconductor wafer. In addition, many conventional layered pedestal configurations have been found to suffer from structural problems and delamination that often result from the stresses of the high temperature operations.

The inventors have now found that the use of the disclosed beryllium oxide (BeO) compositions (with high purity levels and phase component content) results in a pedestal assembly (or in pedestal base plate and shaft components) that demonstrate a synergistic combination of high temperature performance and high chucking force (“clamping pressure”), which may be related to resistivity. Without being bound by theory, it is postulated that the combination of some of the specific components of the BeO composition (in some cases at the disclosed component concentrations) optionally in combination with particular processing parameters leads to advantageous microstructures in the BeO, e.g., grain boundaries and grain size, which, in turn, provides for the combination of high temperature performance and high clamping pressure. Also, without being bound by theory, the disclosed BeO compositions lead to a pedestal base plate having optimal (smaller) quantities of magnesium oxide, silicon dioxide, and/or magnesium trisilicate, which contributes to high bulk resistivity.

Also, the inventors have found that some of the disclosed beryllium oxide (BeO) compositions (in some cases at the disclosed component concentrations) in combination with particular processing parameters unexpectedly leads to an advantageous microstructure (discussed in more detail herein).

Further, the components of the BeO composition have been found to provide for a low dielectric constant, which leads to lower capacitance, which in turn improves unchucking time delays. The disclosed BeO compositions also have been found to demonstrate improved corrosion resistance, improved thermal effusivity, improved thermal diffusivity, improved thermal conductivity, improved specific heat, and lower thermal hysteresis, all of which contribute to the performance synergies disclosed herein.

Conventional ceramic pedestals, e.g., those formed with aluminum nitride, aluminum oxide, silicon dioxide, silicon carbide, silicon nitride, sapphire, zirconia, anodized metals, or graphite as the main components, have been unable to achieve high temperature performance. Nor have they been able to achieve acceptable clamping pressure at these temperatures—clamping pressure has been found to be depleted/lessened, especially at high temperatures.

### Pedestal Assembly

A pedestal assembly is disclosed herein. The pedestal assembly comprises a base plate that is disposed on or atop a shaft. The shaft contains (and is formed from) a first BeO composition containing BeO as well as fluoride ion and/or fluorine. The base plate contains (and is formed from) a second BeO composition containing BeO (at a high purity level, such as at least 95.0 wt %) and optionally fluoride ion and/or fluorine. The BeO in the disclosed compositions, in some embodiments, is synthetic BeO, e.g., BeO that has been manufactured from raw materials (powders), as opposed to natural BeO, which is a solid that occurs in nature. The inventors have discovered that using beryllium oxide as the main component (and optionally the other components discussed herein) in the compositions provides for or contributes to the performance features discussed herein, e.g., high temperature performance and/or superior clamping pressure.

In some embodiments, the disclosed pedestal assemblies (or the base plates thereof) demonstrate a wide range of clamping pressure performance. In some cases, the disclosed pedestal assembly is a Johnsen-Rahbek pedestal. For example, the disclosed pedestal assembly may demonstrate a clamping pressure greater than 133 kPa, e.g., greater than 135 kPa, greater than 140 kPa, greater than 145 kPa, or greater than 150 kPa. In terms of upper limits, the pedestal assembly may demonstrate a clamping pressure less than 160 kPa, e.g., less than 155 kPa, less than 150 kPa, less than 145 kPa, less than 140 kPa, or less than 135 kPa. In terms of ranges, the pedestal assembly may demonstrate a clamping pressure ranging from 133 kPa to 160 kPa, e.g., from 133 kPa to 155 kPa, from 133 kPa to 150 kPa, from 135 kPa to 150 kPa, from 135 kPa to 145 kPa, or from 138 kPa to 143 kPa.

As used herein, the terms “greater than, “less than,” etc. are considered to include the actual numerical limit, e.g., to be read as “greater than or equal to.” The ranges are considered to include the endpoint values.

In other cases, the disclosed pedestal assembly is a coulombic pedestal. For example, the disclosed pedestal assembly may demonstrate a clamping pressure greater than 0.1 kPa, e.g., greater than 0.5 kPa, greater than 1 kPa, greater than 1.3 kPa, greater than 2 kPa, or greater than 4 kPa. In terms of upper limits, the pedestal assembly may demonstrate a clamping pressure less than 15 kPa, e.g., less than 14 kPa, less than 13 kPa, less than 12 kPa, or less than 10 kPa. In terms of ranges, the pedestal assembly may demonstrate a clamping pressure ranging from 0.1 kPa to 15 kPa, e.g., from 0.5 kPa to 14 kPa, from 1 kPa to 14 kPa, from 1.3 kPa to 13 kPa, from 2 kPa to 12 kPa, or from 4 kPa to 10 kPa.

In other cases, the disclosed pedestal assembly is a partial Johnsen-Rahbek/partial coulombic pedestal. For example, the disclosed pedestal assembly may demonstrate a clamping pressure greater than 0.1 kPa, e.g., greater than 1 kPa, greater than 10 kPa, greater than 13 kPa, greater than 20 kPa, greater than 40 kPa, or greater than 60 kPa. In terms of upper limits, the pedestal assembly may demonstrate a clamping pressure less than 160 kPa, e.g., less than 155 kPa, less than 135 kPa, less than 133 kPa, less than 130 kPa, less than 120 kPa, less than 100 kPa, or less than 80 kPa. In terms of ranges, the pedestal assembly may demonstrate a clamping pressure ranging from 0.1 kPa to 160 kPa, e.g., from 1 kPa to 155 kPa, from 1 kPa to 135 kPa, from 1 kPa to 133 kPa, from 10 kPa to 130 kPa, from 13 kPa to 133 kPa, from 20 kPa to 120 kPa, from 40 kPa to 100 kPa, or from 60 kPa to 80 kPa.

In some embodiments, the disclosed pedestal assembly may demonstrate a clamping pressure greater than 0.1 kPa, e.g., greater than 1 kPa, greater than 1.3 kPa, greater than 3 kPa, greater than 5 kPa, greater than 10 kPa, or greater than 20 kPa. In terms of upper limits, the pedestal assembly may demonstrate a clamping pressure less than 70 kPa, e.g., less than 60 kPa, less than 55 kPa, less than 50 kPa, or less than 45 kPa. In terms of ranges, the pedestal assembly may demonstrate a clamping pressure ranging from 0.1 kPa to 70 kPa, e.g., from 1 kPa to 60 kPa, from 1.3 kPa to 55 kPa, from 5 kPa to 50 kPa, or from 10 kPa to 45 kPa.

In some embodiments, the disclosed pedestal assembly may demonstrate a clamping pressure greater than 70 kPa, e.g., greater than 100 kPa, greater than 135 kPa, greater than 150 kPa, greater than 200 kPa, or greater than 250 kPa. In terms of upper limits, the pedestal assembly may demonstrate a clamping pressure less than 550 kPa, e.g., less than 500 kPa, less than 450 kPa, less than 400 kPa, or less than 350 kPa. In terms of ranges, the pedestal assembly may demonstrate a clamping pressure ranging from 70 kPa to 550 kPa, e.g., from 100 kPa to 500 kPa, from 135 kPa to 450 kPa, from 150 kPa to 400 kPa, from 200 kPa to 400 kPa, or from 250 kPa to 350 kPa.

In addition, it has been discovered that the particular compositions and processing parameters lead to property gradients across the thickness of the pedestal base plate and/or over the length of the pedestal shaft. Beneficially, these gradients have been found to better distribute thermal and mechanical stresses that are present in high temperature deposition operations (which can eliminate stress risers). Importantly, these gradients are achieved without requiring discrete layers.

The disclosed pedestal assemblies are unexpectedly able to achieve the aforementioned clamping pressures under more severe operating conditions, e.g., temperatures, pressures, and/or voltages (as compared to conventional pedestal assemblies). In some embodiments, pedestals are able to achieve the aforementioned clamping pressures at temperatures greater than 400° C., e.g., greater than 500° C., greater than 600° C., greater than 700° C., or greater than 800° C. and/or at voltages greater than 300V, e.g., greater than 400V, greater than 450V, greater than 500V, greater than 550V, greater than 600V, or greater than 650V. In contrast, conventional aluminum nitrate pedestals have been found to be highly ineffective clamping under severe operating conditions—in most cases, the conventional aluminum nitrate decompose under these conditions and are not able to provide limited (if any) clamping capability.

### Shaft

The disclosure also relates to a shaft. The shaft comprises a BeO composition, e.g., the aforementioned first BeO composition. Due to the composition and optionally the processing thereof, the shaft demonstrates the superior performance characteristics and microstructure disclosed herein. In particular, the shaft has average grain boundaries greater than 0.1 micron or an amorphous grain structure, as discussed herein. In some cases, the shaft has advantageous property gradients over the length of the shaft (see discussion below).

The first BeO composition comprises, as the main component, BeO. The BeO may be present in an amount ranging from 50 wt % to 99.9 wt %, e.g., from 75 wt % to 99.9 wt %, from 85 wt % to 99.7 wt %, from 90 wt % to 99.7 wt %, or from 92 wt % to 99.5 wt %. In terms of lower limits, the first BeO composition may comprise greater than 50 wt % BeO, e.g., greater than 75 wt %, greater than 85 wt %, greater than 90 wt %, greater than 92 wt %, greater than 95 wt %, greater than 98 wt %, or greater than 99 wt %. In terms of upper limits, the first BeO composition may comprise less than 99.9 wt % BeO, e.g., less than 99.8 wt %, less than 99.7 wt %, less than 99.6 wt %, less than 99.5 wt %, or less than 99.0 wt %.

In some embodiments, the first BeO composition, e.g., the BeO composition of the shaft, comprises from 1 ppb to 1000 ppm fluoride ion and/or fluorine, e.g., from 10 ppb to 800 ppm, from 100 ppb to 500 ppm, from 500 ppb to 500 ppm, from 1 ppm to 300 ppm, from 25 ppm to 250 ppm, from 25 ppm to 200 ppm, from 50 ppm to 150 ppm, or from 75 ppm to 125 ppm. In terms of lower limits, the first BeO composition may comprise greater than 1 ppb fluoride ion and/or fluorine, e.g., greater than 10 ppb, greater than 100 ppb, greater than 500 ppb, greater than 1 ppm, greater than 2 ppm, greater than 50 ppm or greater than 75 ppm. In terms of upper limits, the first BeO composition may comprise less than 1000 ppm fluoride ion and/or fluorine, e.g., less than 800 ppm, less than 500 ppm, less than 300 ppm, less than 250 ppm, less than 200 ppm, less than 150 ppm, or less than 125 ppm. In some embodiments, the first BeO composition is processed to achieve the fluorine/fluoride ion concentration, e.g., by conducting separation operations so as to arrive at the desired fluorine/fluoride ion concentration. In some cases, the desired fluorine/fluoride ion concentration does not occur naturally and requires such separation operations. Further, the disclosed amounts of fluorine/fluoride ion in the BeO compositions have surprisingly been found to provide unexpected benefits. It is believed that the fluorine/fluoride ion (optionally in the disclosed amounts) contributes to/leads to a microstructure that is surprisingly effective in interrupting phonon wave function, phonon transport, and/or transmission (via scattering).

In some embodiments, the first BeO composition comprises more fluoride ion and/or fluorine than the second BeO composition. The inventors have surprisingly found that the differences in the fluoride ion and/or fluorine content from base plate to shaft are important at least because of the aforementioned phonon interruption properties. In some embodiments, the first BeO composition comprises at least 10% more fluoride ion and/or fluorine than the second BeO composition, e.g., at least 20%, at least 30, at least 50%, at least 75%, or at least 100%.

In some cases, the first BeO composition further comprises magnesium oxide. For example, the first BeO composition may comprise 1 ppb to 50 wt % ppm magnesium oxide, e.g., from 100 ppm to 25 wt %, from 500 ppm to 10 wt %, from 0.1 wt % to 10 wt %, from 0.5 wt % to 8 wt %, from 0.5 wt % to 5 wt %, from 0.7 wt % to 4 wt %, or from 0.5 wt % to 3.5 wt %. In terms of lower limits, the first BeO composition may comprise greater than 1 ppb magnesium oxide, e.g., greater than 10 ppb, greater than 100 ppm, greater than 500 ppm, greater than 0.1 wt %, greater than 0.5 wt %, greater than 0.7 wt %, or greater than 1 wt %. In terms of upper limits, the first BeO composition may comprise less than 50 wt % magnesium oxide, e.g., less than 25 wt %, less than 10 wt %, less than 8 wt %, less than 5 wt %, less than 4 wt %, or less than 3.5 wt %.

In some particular embodiments, the first BeO composition comprises silicon dioxide. For example, the first BeO composition may comprise 1 ppb to 50 wt % ppm silicon dioxide, e.g., from 100 ppm to 25 wt %, from 500 ppm to 10 wt %, from 0.1 wt % to 10 wt %, from 0.5 wt % to 8 wt %, from 0.5 wt % to 5 wt %, from 0.7 wt % to 4 wt %, or from 0.5 wt % to 3.5 wt %. In terms of lower limits, the first BeO composition may comprise greater than 1 ppb silicon dioxide, e.g., greater than 10 ppb, greater than 100 ppm, greater than 500 ppm, greater than 0.1 wt %, greater than 0.5 wt %, greater than 0.7 wt %, or greater than 1 wt %. In terms of upper limits, the first BeO composition may comprise less than 50 wt % silicon dioxide, e.g., less than 25 wt %, less than 10 wt %, less than 8 wt %, less than 5 wt %, less than 4 wt %, or less than 3.5 wt %.

The first BeO composition may comprise magnesium trisilicate. For example, the first BeO composition may comprise from 1 ppb to 5 wt % magnesium trisilicate, e.g., from 1 ppm to 2 wt %, from 100 ppm to 2 wt %, from 500 ppm to 1.5 wt %, from 1000 ppm to 1 wt %, from 2000 ppm to 8000 ppm, from 3000 ppm to 7000 ppm, or from 4000 ppm to 6000 ppm. In terms of lower limits the first BeO composition may comprise greater than 1 ppb magnesium trisilicate, e.g., greater than 1 ppm, greater than 100 ppm, greater than 500 ppm, greater than 1000 ppm, greater than 2000 ppm, greater than 3000 ppm, or greater than 4000 ppm. In terms of upper limits, the first BeO composition may comprise less than 5 wt % magnesium trisilicate, e.g., less than 2 wt %, less than 1.5 wt %, less than 1 wt %, less than 8000 ppm, less than 7000 ppm, or less than 6000 ppm.

In some cases, the first BeO composition further comprises alumina. For example, the first BeO composition may comprise 1 ppb to 50 wt % ppm alumina, e.g., from 100 ppm to 25 wt %, from 500 ppm to 10 wt %, from 0.1 wt % to 10 wt %, from 0.5 wt % to 8 wt %, from 0.5 wt % to 5 wt %, from 0.7 wt % to 4 wt %, or from 0.5 wt % to 3.5 wt %. In terms of lower limits, the first BeO composition may comprise greater than 1 ppb alumina, e.g., greater than 10 ppb, greater than 100 ppm, greater than 500 ppm, greater than 0.1 wt %, greater than 0.5 wt %, greater than 0.7 wt %, or greater than 1 wt %. In terms of upper limits, the first BeO composition may comprise less than 50 wt % alumina, e.g., less than 25 wt %, less than 10 wt %, less than 8 wt %, less than 5 wt %, less than 4 wt %, or less than 3.5 wt %.

In some cases, the first BeO composition further comprises sulfites. For example, the first BeO composition may comprise 1 ppb to 10000 ppm sulfites, e.g., from 1 ppm to 5000, from 1 ppm to 2000 ppm, from 10 ppm to 1500 ppm, from 10 ppm to 1000 ppm, from 10 ppm to 500 ppm, from 25 ppm to 200 ppm, or from 50 ppm to 150 ppm. In terms of lower limits, the first BeO composition may comprise greater than 1 ppb sulfites, e.g., greater than 1 ppm, greater than 10 ppm, greater than 25 ppm, or greater than 50 ppm. In terms of upper limits, the first BeO composition may comprise less than 10000 ppm sulfites, e.g., less than 5000 ppm, less than 2000 ppm, less than 1500 ppm, less than 1000 ppm, less than 500 ppm, less than 300 ppm, less than 200 ppm, or less than 150 ppm.

In some cases, the first BeO composition comprises lower amounts of non-BeO ceramics, e.g., oxide ceramics. For example, the first beryllium oxide composition may comprise less than 75 wt % non-BeO ceramics, e.g., less than 50 wt %, less than 25 wt %, less than 10 wt %, less than 5 wt %, or less than 1 wt %. In terms of ranges, the first BeO composition may comprise from 1 wt % to 75 wt % non-BeO ceramics, e.g., from 5 wt % to 50 wt %, from 5 wt % to 25 wt %, or from 1 to 10 wt %.

The first BeO composition may further comprise other components such as boron, barium, sulfur, or lithium, or combinations thereof including oxides, alloys, composites, or allotropes, or combinations thereof. The first BeO composition may comprise these components in amounts ranging from 1 ppb to 1 wt % ppm, e.g., from 10 ppb to 0.5 wt %, from 10 ppb to 1000 ppm, from 10 ppb to 900 ppm, from 50 ppb to 800 ppm, from 500 ppb to 000 ppm, from 1 ppm to 600 ppm, from 50 ppm to 500 ppm, from 50 ppm to 250 ppm, or from 50 ppm to 150 ppm. In terms of lower limits, the first BeO composition may comprise greater than 1 ppb of these components, e.g., greater than 10 ppm, greater than 50 ppb, greater than 100 ppb, greater than 500 ppb, greater than 1 ppm, greater than 50 ppm, greater than 100 ppm, or greater than 200 ppm. In terms of upper limits, the first BeO composition may comprise less than 1 wt % of these components, e.g., less than 0.5 wt %, less than 1000 ppm, e.g., less than 900 ppm, less than 800 ppm, less than 700 ppm, less than 600 ppm, less than 500 ppm, less than 250 ppm, or less than 150 ppm.

In some embodiments, the first BeO composition comprises less than 75 wt % of non-BeO ceramics, e.g., aluminum nitride, e.g., less than 50 wt %, less than 25 wt %, less than 10 wt %, less than 5 wt %, less than 3 wt %, or less than 1 wt %. In terms of ranges, the first BeO composition may comprise from 0.01 wt % to 75 wt % non-BeO ceramics, e.g., from 0.05 wt % to 50 wt %, from 0.05 wt % to 25 wt %, or from 0.1 to 10 wt %.

Other components may also be present, for example, aluminum (different from the aforementioned alumina), lanthanum, magnesium (other than the aforementioned magnesium oxide or magnesium trisilicate), silicon (other than the aforementioned silicon dioxide and magnesium trisilicate), or yttria or combinations thereof including oxides, alloys, composites, or allotropes, or combinations thereof. These above ranges and limits are applicable to these additional components.

### Second Phase

In some cases, the shaft and/or the base plate comprise a primary phase (first phase) and a secondary phase (second phase). The primary phase comprises the grains of material and the secondary phase comprises the material that forms the grain boundaries, e.g., the material between the grains. The compositions of the primary phase and the secondary phase may differ from one another. The respective compositions of the secondary phase in the shaft and base plate may affect the performance properties thereof, e.g., thermal conductivity, (theoretical) density, and the ability to scatter phonons, among others. Generally, the secondary phase will be a relatively small portion of the overall composition of the shaft and/or the base plate. In some cases, the shaft will contain more secondary phase than the base plate, e.g., at least 5% more, at least 10% more, at least, 25% more, or at least 50% more, which contributes to improved performance of the assembly.

In some embodiments, the shaft comprises from 0.001 wt % to 50 wt % second phase, e.g., from 0.01 wt % to 25 wt %, from 0.01 wt % to 10 wt %, from 0.05 wt % to 10 wt %, 0.1 wt % to 10 wt %, from 0.1 wt % to 5 wt %, from 0.5 wt % to 5 wt %, or from 0.5 wt % to 3 wt %. In terms of upper limits, the shaft may comprise less than 50 wt % second phase, e.g., less than 25 wt %, less than 10 wt %, less than 5 wt %, less than 3 wt % or less than 2 wt %. In terms of lower limits, the shaft may comprise greater than 0.001 wt % second phase, e.g., greater than 0.01 wt %, greater than 0.05 wt %, greater than 0.1 wt %, greater than 0.5 wt %, or greater than 1 wt %. The weight percentages are based on the total weight of the shaft.

In some embodiments, the base plate comprises from 0.05 wt % to 10 wt % second phase, e.g., from 0.05 wt % to 5 wt %, from 0.1 wt % to 5 wt %, from 0.1 wt % to 3 wt, or from 0.1 wt % to 1 wt %. In terms of upper limits, the base plate may comprise less than 10 wt % second phase, e.g., less than 5 wt %, less than 3 wt %, less than 2 wt %, or less than 1 wt %. In terms of lower limits, the shaft may comprise greater than 0.05 wt % second phase, e.g., greater than 0.1 wt %, greater than 0.2 wt %, greater than 0.5 wt %, greater than 0.7 wt %, or greater than 1 wt %. The weight percentages are based on the total weight of the base plate.

In some cases, the second phase may comprise non-BeO components. For example, the second phase of the first BeO composition that makes up the shaft may comprise magnesia (MgO), silica (SiO₂), alumina, yttria, titania, lithia, lanthana, or magnesium trisilicate, or mixtures thereof. The first BeO composition (and the shaft made therefrom) comprises non-BeO components, each of which may be present in an amount ranging from 1 ppb to 500 ppm, e.g., from 500 ppb to 500 ppm, from 1 ppm to 300 ppm, from 1 ppm to 200 ppm, from 10 ppm to 200 ppm, from 50 ppm to 150 ppm, or from 75 ppm to 125 ppm. In terms of upper limits, the first BeO composition may comprise non-BeO components, each being present in an amount less than 500 ppm, e.g., less than 300 ppm, less than 200 ppm, less than 150 ppm, or less than 125 ppm. In terms of lower limits, the first BeO composition may comprise non-BeO components, each being present in an amount greater than 1 ppb, e.g., greater than 500 ppb, greater than 1 ppm, greater than 10 ppm, greater than 25 ppm, greater than 50 ppm, greater than 75 ppm, or greater than 100 ppm. These weight percentages are based on the total weight of the first BeO composition, e.g., the total weight of the shaft.

In some particular embodiments the first BeO composition comprises 1 ppb to 10000 ppm second phase magnesium oxide, e.g., from 100 ppm to 9000 ppm, from 2000 ppm to 10000 ppm, from 5000 ppm to 10000 ppm, from 5000 ppm to 9000 ppm, from 6000 ppm to 9000 ppm, or from 7000 ppm to 8000 ppm. In terms of lower limits, the first BeO composition may comprise greater than 1 ppb second phase magnesium oxide, e.g., greater than 10 ppb, greater than 100 ppb, greater than 1 ppm, greater than 50 ppm, greater than 100 ppm, greater than 200 ppm, greater than 1000 ppm, greater than 2000 ppm, greater than 3000 ppm, greater than 4000 ppm, greater than 5000 ppm, greater than 6000 ppm, or greater than 7000 ppm. In terms of upper limits, the first BeO composition may comprise less than 10000 ppm second phase magnesium oxide, e.g., less than 9000 ppm, less than 8000 ppm, less than 7000 ppm, less than 6000 ppm, less than 5000 ppm, or less than 4000 ppm.

In some particular embodiments the first BeO composition comprises from 1 ppb to 5000 ppm second phase silicon dioxide, e.g., from 100 ppb to 1000 ppm, from 100 ppb to 500 ppm, from 1 ppm to 500 ppm, from 1 ppm to 100 ppm, from 5 ppm to 50 ppm, from 1 ppm to 20 ppm, or from 2 ppm to 10 ppm. In terms of lower limits the first BeO composition comprises greater than 1 ppb second phase silicon dioxide, e.g., greater than 10 ppb, greater than 100 ppb, greater than 200 ppb, greater than 500 ppb, greater than 1 ppm, greater than 2 ppm, greater than 5 ppm, or greater than 7 ppm. In terms of upper limits, the first BeO composition comprises less than 5000 ppm second phase silicon dioxide, e.g., less than 1000 ppm, less than 500 ppm, less than 100 ppm, less than 50 ppm, less than 20 ppm, or less than 10 ppm.

In some particular embodiments the first BeO composition comprises from 1 ppb to 5000 ppm second phase alumina, e.g., from 100 ppb to 1000 ppm, from 100 ppb to 500 ppm, from 1 ppm to 500 ppm, from 1 ppm to 100 ppm, from 5 ppm to 50 ppm, from 1 ppm to 20 ppm, or from 2 ppm to 10 ppm. In terms of lower limits the first BeO composition comprises greater than 1 ppb second phase alumina, e.g., greater than 10 ppb, greater than 100 ppb, greater than 200 ppb, greater than 500 ppb, greater than 1 ppm, greater than 2 ppm, greater than 5 ppm, or greater than 7 ppm. In terms of upper limits, the first BeO composition comprises less than 5000 ppm second phase alumina, e.g., less than 1000 ppm, less than 500 ppm, less than 100 ppm, less than 50 ppm, less than 20 ppm, or less than 10 ppm.

The second phase of the first BeO composition may further comprise other components such as carbon, calcium, cerium, iron, hafnium, molybdenum, selenium, titanium, yttrium, or zirconium, or combinations thereof including oxides, alloys, composites, or allotropes, or combinations thereof. These components may also be present in the first phase of the first BeO composition (and in the shaft). For example, the first BeO composition may comprise these components in an amount ranging from 1 ppb to 5 wt %, e.g., from 10 ppb to 3 wt %, from 100 ppb to 1 wt %, from 1 ppm to 1 wt %, from 1 ppm to 5000 ppm, from 10 ppm to 1000 ppm, from 50 ppm to 500 ppm, or from 50 ppm to 300 ppm. In terms of upper limits, these components may be present in an amount less than 5 wt %, e.g., less than 3 wt %, less than 1 wt %, less than 5000 ppm, less than 1000 ppm, less than 500 ppm, or less than 300 ppm. In terms of lower limits, these components may be present in an amount greater than 1 ppb, e.g., greater than 10 ppb, greater than 100 ppb, greater than 1 ppm, greater than 10 ppm, or greater than 50 ppm.

It has been discovered that the particular composition of the first BeO composition optionally in conjunction with the processing thereof provides for a specific microstructure that is particularly beneficial for high temperature performance. Without being bound by theory, it is postulated that the magnesium oxide, silicon dioxide, and/or magnesium trisilicate unexpectedly increases grain boundaries and/or decreases grain size, which creates a more thermally restrictive barrier between the grains, e.g., establishes a barrier choke between the grains. This improved microstructure is believed to contribute to the improved high temperature performance. In some embodiments, the first BeO composition has average grain boundaries greater than 0.05 microns, e.g., greater than 0.07 microns, greater than 0.09 microns, greater than 0.1 micron, greater than 0.3 microns, greater than 0.5 microns, greater than 0.7 microns, greater than 1.0 micron, greater than 2 microns, greater than 4 microns, greater than 5 microns, greater than 7 microns, or greater than 10 microns. In terms of ranges, the first BeO composition has average grain boundaries ranging from 0.05 microns to 25 microns, e.g., from 0.05 microns to 15 microns, from 0.07 microns to 12 microns, from 0.1 micron to 10 microns, from 0.5 microns to 10 microns, or from 1 micron to 7 microns. In addition to the magnesium oxide, silicon dioxide, and/or magnesium trisilicate, it is postulated that other trace components disclosed herein may further beneficially contribute to the improvements, although perhaps not to the same degree.

In some embodiments, the BeO compositions have an average grain size less than 100 microns, e.g., less than 90 microns, less than 75 microns, less than 60 microns, less than 50 microns, less than 40 microns, less than 35 microns, less than 25 microns, less than 15 microns, less than 10 microns, or less than 5 microns. In terms of ranges, the BeO compositions may have an average grain size ranging from 0.1 micron to 100 microns, e.g., from 1 micron to 75 microns, from 1 micron to 35 microns, from 3 microns to 25 microns, or from 5 microns to 15 microns. This smaller grain size has been found to beneficially prevent heat transfer, thus contributing to or enhancing high temperature performance—the transfer of heat from the plate to the opposite end of the shaft is limited, which allows the base plate and the adjacent end of the shaft to remain hot while the opposing end of the shaft (away from the base plate) remains cool. It is postulated that the particular grain size also has an advantageous effect on phonon scattering.

In some cases, the shaft comprises a “stub” portion (thermal choke portion). The stub portion may, in some cases, be a ring or washer. The stub portion may be employed to moderate shaft temperature. The coefficient of thermal expansion similar to the remainder of the shaft, e.g., within 25%, within 20%, within 15%, within 10%, within 5%, within 3% or within 1%.

### Base Plate

The disclosure also relates to a base plate. The base plate has a top and a bottom and comprises a BeO composition, e.g., the aforementioned second BeO composition. Due to the composition and optionally the processing thereof, the base plate demonstrates the superior performance characteristics disclosed herein. In particular, the base plate demonstrates a clamping pressure described herein.

In some embodiments, the second BeO composition, e.g., the BeO composition of the base plate, comprises BeO at a high purity level. The purity level of the beryllium oxide composition for the base plate (optionally along with the processing thereof to from the base plate) has been found to advantageously contribute to high temperature performance. And the BeO utilized for the second BeO composition (or the first BeO composition for that matter) may be processed to achieve the specific purity levels. Further, the base plate has few of any discrete (laminated) layers, e.g., less than 3, less than 2. In some cases, the base plate has no discrete layers, which beneficially eliminates conventional problems of delamination and deterioration.

The BeO may be present in an amount ranging from 50 wt % to 99.99 wt %, e.g., from 75 wt % to 99.95 wt %, from 75 wt % to 99.9 wt %, from 85 wt % to 99.7 wt %, from 90 wt % to 99.7 wt %, or from 92 wt % to 99.5 wt %. In terms of lower limits, the first BeO composition may comprise greater than 50 wt % BeO, e.g., greater than 75 wt %, greater than 85 wt %, greater than 90 wt %, greater than 92 wt %, greater than 95 wt %, greater than 98 wt %, or greater than 99 wt %. In terms of upper limits, the first BeO composition may comprise less than 99.99 wt % BeO, e.g., less than 99.95 wt %, less than 99.90 wt %, less than 99.70 wt %, less than 99.50 wt %, or less than 99.0 wt %. In some embodiments, the BeO concentration of the second BeO composition is greater than the BeO concentration of the first BeO composition, e.g., at least 1% greater, at least 2% greater, at least 3% greater, at least 5% greater, at least 7% greater, or at least 10% greater. Stated another way, the base plate BeO composition may be more pure than the shaft BeO composition, which is advantageous because intrinsic, dielectric, and thermal properties have been found to be more important toward the top of the plate, more so than in the shaft.

Without being bound by theory, it is believed that the synergistic performance properties of the base plate (or shaft), e.g., improved high temperature performance, superior clamping pressure, etc., are at least in part a function of the BeO concentration. Conventional base plates (or shafts), e.g., those that comprise non-BeO ceramics, e.g., aluminum nitride, aluminum oxide, silicon dioxide, or graphite, as the main component have been found to be unable to achieve such performance. In some embodiments, the second BeO composition comprises less than 5 wt % of these non-BeO ceramics, e.g., less than 3 wt %, less than 1 wt %, less than 0.5 wt %, or less than 0.1 wt %. In terms of ranges, the second BeO composition may comprise from 0.01 wt % to 5 wt % non-BeO ceramics, e.g., from 0.05 wt % to 3 wt %, from 0.05 wt % to 1 wt %, or from 0.1 to 1 wt %.

The second BeO composition may further comprise fluorine/fluoride ion. And the fluorine/fluoride ion may be present in the amounts discussed above with respect to the first BeO composition. As noted above, however, in some cases, the second BeO composition comprises more fluoride ion and/or fluorine than the second BeO composition.

In some cases, the second BeO composition may further comprise magnesium oxide, silicon dioxide, and/or magnesium trisilicate. It has been found that the concentrations of these components, and the effects thereof on microstructure (see discussion above), unexpectedly provides for a pedestal base plate that demonstrates a low corrosion loss and a high bulk resistivity. And the low resistivity (optionally in combination with other characteristics provides for improved clamping performance (in combination with improved high temperature performance).

In some cases, the second BeO composition further comprises magnesium oxide. For example, the second BeO composition may comprise 1 ppb to 10 wt % ppm magnesium oxide, e.g., from 1 ppm to 5 wt %, from 10 ppm to 1 wt %, from 100 ppm to 1 wt %, from 500 ppm to 8000 ppm, from 1000 ppm to 8000 ppm, from 3000 ppm to 7000 ppm, or from 4000 ppm to 6000 ppm. In terms of lower limits, the second BeO composition may comprise greater than 1 ppb magnesium oxide, e.g., greater than 10 ppb, greater than 1 ppm, greater than 10 ppm, greater than 100 ppm, greater than 500 ppm, greater than 1000 ppm, greater than 2000 ppm, greater than 3000 ppm, or greater than 4000 ppm. In terms of upper limits, the first BeO composition may comprise less than 10 wt % magnesium oxide, e.g., less than 5 wt %, less than 1 wt %, less than 8000 ppm, less than 7000 ppm, or less than 6000 ppm.

In some cases, the second BeO composition further comprises silica, alumina, yttria, titania, lithia, lanthana, or magnesium trisilicate, or mixtures thereof. These components may be present in the amounts noted for magnesium oxide in the second BeO composition.

In some cases, the second BeO composition further comprises lithia in smaller concentrations, e.g., from 1 ppb to 1 wt %, e.g., from 100 ppb to 0.5 wt %, from 1 ppm to 0.1 wt %, from 100 ppm to 900 ppm, from 200 ppm to 800 ppm, from 300 ppm to 700 ppm, or from 400 ppm to 600 ppm. In terms of lower limits, the second BeO composition may comprise greater than 1 ppb lithia, e.g., greater than 100 ppb, greater than 1 ppm, greater than 100 ppm, greater than 200 ppm, greater than 200 ppm, greater than 300 ppm, or greater than 400 ppm. In terms of upper limits, the first BeO composition may comprise less than 10 wt % lithia, e.g., less than 1 wt %, less than 0.5 wt %, less than 0.1 wt % ppm, less than 900 ppm, less than 800 ppm, less than 700 ppm, or less than 600 ppm.

The second BeO composition may further comprise other components such as carbon, calcium, cerium, iron, hafnium, molybdenum, selenium, titanium, yttrium, or zirconium, or combinations thereof including oxides, alloys, composites, or allotropes, or combinations thereof. These components may also be present in the second phase of the second BeO composition (and in the base plate). For example, the second BeO composition may comprise these components in an amount ranging from 1 ppb to 5 wt %, e.g., from 10 ppb to 3 wt %, from 100 ppb to 1 wt %, from 1 ppm to 1 wt %, from 1 ppm to 5000 ppm, from 10 ppm to 1000 ppm, from 50 ppm to 500 ppm, or from 50 ppm to 300 ppm. In terms of upper limits, these components may be present in an amount less than 5 wt %, e.g., less than 3 wt %, less than 1 wt %, less than 5000 ppm, less than 1000 ppm, less than 500 ppm, or less than 300 ppm. In terms of lower limits, these components may be present in an amount greater than 1 ppb, e.g., greater than 10 ppb, greater than 100 ppb, greater than 1 ppm, greater than 10 ppm, or greater than 50 ppm.

In some embodiments, the second BeO composition may further comprise other components mentioned above with respect to the first BeO composition. The compositional ranges and limits are applicable to the second BeO composition as well.

In some embodiments, the first beryllium oxide composition comprises more magnesium oxide and/or magnesium trisilicate and/or other components than the second beryllium composition. The benefits for these components with respect to the microstructure are discussed above.

### Second Phase

In some cases, the second phase of the second BeO composition may comprise non-BeO components. For example, the second phase of the second BeO composition that makes up the base plate may comprise magnesia, silica, alumina, yttria, titania, lithia, lanthana, or magnesium trisilicate, or mixtures thereof. The second BeO composition (and the base plate made therefrom) comprises non-BeO second phase components, each of which may be present in an amount ranging from 1 ppb to 500 ppm, e.g., from 500 ppb to 500 ppm, from 1 ppm to 300 ppm, from 1 ppm to 200 ppm, from 10 ppm to 200 ppm, from 50 ppm to 150 ppm, or from 75 ppm to 125 ppm. In terms of upper limits, the first BeO composition may comprise non-BeO second phase components, each being present in an amount less than 500 ppm, e.g., less than 300 ppm, less than 200 ppm, less than 150 ppm, or less than 125 ppm. In terms of lower limits, the second BeO composition may comprise non-BeO components, each being present in an amount greater than 1 ppb, e.g., greater than 500 ppb, greater than 1 ppm, greater than 10 ppm, greater than 25 ppm, greater than 50 ppm, greater than 75 ppm, or greater than 100 ppm. These weight percentages are based on the total weight of the first BeO composition, e.g., the total weight of the shaft.

### Performance

In addition to clamping pressure, the base plate has been found to demonstrate synergistic combinations of performance features. For example, the base plate may demonstrate superior performance in terms of one or more of the following:
Temperature uniformity
Bulk resistivity
Corrosion loss
Dielectric constant.

The numerical ranges and limits for these performance characteristics are described in detail below.

In some embodiments, the base plate has a consistent coefficient of thermal expansion (CTE) from top-to-bottom, e.g., the CTE does not vary from top-to-bottom. For example, the coefficient of thermal may varies from top-to-bottom by less than 25%, e.g., less than 20%, less than 15%, less than 10%, less than 7%, less than 5%, less than 3%, or less than 1%.

In one embodiment, the pedestal, e.g., the base plate, demonstrates low (if any) cycle cleaning time. During operation, it may be necessary to clean the pedestal, the wafer substrate, and/or the chamber, cleaning/removing built-up overspray. Conventionally, pedestal assemblies require a cooling step, e.g., at least an hour to get to 300° C., to get to a temperature suitable for cleaning, and then an additional heating step, e.g., at least another hour to return to temperature. And the wafer must stabilize with these temperature changes. Because of the composition of the disclosed pedestal/base plate, cooling (or the subsequent re-heating) is not required—cleaning can take place at operating temperature, and the cycle cleaning time is minimized (if not eliminated) and the wafer does not have to stabilize (as much). In some embodiments, the cycle cleaning time of the pedestal/base plate is less than 2 hours, e.g., less than 1.5 hours, less than 1 hour, less than 45 minutes, less than 30 minutes, less than 20 minutes, less than 10 minutes, or less than 5 minutes.

In some cases, the disclosure further relates to a process for cleaning a contaminated pedestal assembly/wafer/chamber. The process comprises the steps of providing to a chamber the pedestal assembly and a wafer with the wafer disposed atop the pedestal assembly and heating the wafer to an operating temperature of at least 400° C., at least 450° C., at least 500° C., at least 550° C., at least 600° C., at least 650° C., or at least 700° C. Once at production temperature (and if contaminated) the process comprises the steps of cooling the wafer by less than 150° C., e.g., less than 100° C., less than 50° C., less than 25° C., or less than 10° C., (or no cooling at all for BeO) to a cooled temperature and cleaning the plate at the cooled temperature. In some embodiments, the process further comprises the step of re-heating the wafer to an operating temperature of at least 400° C., at least 450° C., at least 500° C., at least 550° C., at least 600° C., at least 650° C., or at least 700° C. Importantly, a cleaning cycle time from the cooling step to the reheating step is shorter than conventional methods, e.g., less than 2 hours, e.g., less than 1.5 hours, less than 1 hour, less than 45 minutes, less than 30 minutes, less than 20 minutes, less than 10 minutes, or less than 5 minutes. Beneficially, because of the composition of the disclosed pedestal/base plate, cooling (or the subsequent re-heating) is not required or is minimized—cleaning can take place at operating temperature (or only slightly below, and the cycle cleaning time is minimized (if not eliminated) and the wafer does not have to stabilize (as much).

The disclosed base plate may be larger in size than some conventional base plates, while still demonstrating the superior performance characteristics mentioned herein. Conventionally, manufacturers have struggled with producing larger base plates that demonstrate suitable characteristics. As is known in the art, as the size of a base plate increases, so do the difficulties of maintaining performance and producing the base plate. Some reasons include the higher CTE of conventional pedestal materials, which detrimentally leads to cracking problems, and size limits of conventional commercial machines. In some embodiments, the minimum transverse measurement across the base plate is at least 100 mm, e.g., at least 125 mm, at least 150 mm, at least 175 mm, at least 200 mm, at least 225 mm, at least 250 mm, at least 300 mm, at least 400 mm, at least 500 mm, at least 750 mm, or at least 1000 mm.

The base plate, in some embodiments, has a flatness with a camber of less than 50 microns across a distance of 300 mm, e.g., less than 40 microns, less than 30 microns, less than 25 microns, less than 15 microns, less than 10 microns, or less than 5 microns.

In some cases, the base plate further comprises a mesa (stand-off). A mesa is used to elevate the wafer. In some embodiments, the mesa(s) protrude upwardly from the top surface of the base plate. The mesa(s) may have an average height ranging from 1 micron to 50 microns, e.g., from 1.5 microns to 40 microns, from 2 microns to 30 microns, from 2 microns to 20 microns, from 2.5 microns to 18 microns, or from 5 microns to 15 microns. In terms of lower limits, the mesa(s) may have an average height greater than 1 micron, e.g., greater than 1.5 microns, greater than 2 microns, greater than 2.5 microns, greater than 3 microns, or greater than 5 microns. In terms of upper limits, the mesa(s) may have an average height less than 50 microns, e.g., less than 40 microns, less than 30 microns, less than 20 microns, less than 18 microns, or greater than 15 microns.

In some cases, the base plate further comprises a heating element encapsulated therein. In some instances, the heating element is a coiled or crimped heating element. The combination of the BeO composition and/or the crimped or coiled heating element unexpectedly provides improved temperature uniformity (see discussion below), as compared to conventional base plates that employ non-BeO ceramics and/or other types of heating elements.

The base plate may further comprise other hardware, e.g., antennae. These features are discussed in more detail below. In some cases, the antennae and/or to heating element comprise niobium and/or platinum and/or titanium. The inventors have found that the niobium and/or platinum and/or titanium, when employed with the BeO compositions provide for unexpected performance in terms of synergies in coefficients of thermal expansion, as well as corrosion resistance properties and electrical resistance. In some cases, these metals, when employed as hardware, have a thermal compatibility factor that are synergistically perform well with BeO materials. The thermal compatibility factor has been found to prevent stress induced failures, e.g., due to temperature cycling.

### Base Plate Gradient Concepts/Performance

The disclosure also relates to a base plate that is designed to have various property gradients from top-to-bottom. These base plates may be produced by utilizing a multiple powders each of which having differing properties to form a precursor, then heating the precursor to form the base plate with property gradients. Importantly, the resultant base plate has no discrete layers, which provides for benefits over layered base plate assemblies.

In some embodiments, the base plates are produced from a two or more grades of raw BeO powders. In one embodiment, the top surface comprises a first grade, the bottom comprises a second grade, and a middle region comprises a mixture of the first and second grades. For example, the first grade may be a higher purity/higher thermal conductivity/higher (theoretical) density material/lower porosity material, the second grade may be a lower purity/lower thermal conductivity/lower (theoretical) density/higher porosity material. Of course, various other numbers and combinations of raw BeO powders are considered.

The base plate may demonstrate one or more of the following desirable performance gradients.
a decreasing top-to-bottom thermal conductivity gradient
a decreasing top-to-bottom resistivity gradient
a decreasing top-to-bottom purity gradient
a decreasing top-to-bottom theoretical density gradient
an increasing top-to-bottom dielectric constant gradient.

Each of these performance gradients has a “top value,” as measured at the top of the plate, and a “bottom value,” as measured at the bottom of the plate. The endpoints of the ranges herein may be utilized as upper and lower limits. For example, the 231 to 350 W/mK range may generate and upper limit of less than 350 W/mK and a lower limit of 231 W/mK.

Thermal conductivity: In some embodiments, the base plate has a top thermal conductivity ranging from 125 to 400 W/mK, when measured at room temperature, e.g., from 231 to 350 W/mK, from 250 to 350 W/mK, from 265 to 335 W/mK, or from 275 to 325 W/mK. The base plate may have a bottom thermal conductivity ranging from 146 to 218 W/mK, when measured at room temperature, e.g., from 150 to 215 W/mK, from 160 to 205 W/mK, from 165 to 200 W/mK, or from 170 to 190 W/m-K. In terms of upper limits, the base plate may have a thermal conductivity less than 400 W/m-K at room temperature, e.g., less than 375 W/mK, less than 350 W/mK, less than 300 W/mK, less than 275 W/mK, less than 255 W/mK, or less than 250 W/mK.

The base plate may have a top thermal conductivity ranging from 25 to 105 W/mK, when measured at 800° C., e.g., from 35 to 95 W/mK, from 45 to 85 W/mK, or from 55 to 75 W/mK. The base plate may have a bottom thermal conductivity ranging from 1 to 21 W/mK, when measured at 800° C., e.g., from 3 to 20 W/mK, from 5 to 15 W/mK, from 7 to 13 W/mK, or from 9 to 11 W/mK.

Generally the bottom thermal conductivity will be less than the top thermal conductivity. The top thermal conductivity may be at least 6% greater than the bottom thermal conductivity, when measured at room temperature or at 800° C. or independent of measuring temperature, e.g., at least 10% greater, at least 20% greater, at least 35% greater, at least 50% greater, at least 100% greater or at least 200% greater.

Resistivity: In some cases, a top resistivity, at room temperature, ranges from 1×10⁵ to 1×10¹⁶ ohm-m, e.g., from 1×10⁶ to 1×10¹⁶, from 1×10⁷ to 5×10¹⁵, from 1×10⁸ to 1×10¹⁵, or from 1×10⁹ to 1×10¹⁵. A bottom resistivity may be less than the top resistivity. The bottom resistivity may range from 1×10⁵ to 1×10¹⁶ ohm-m, e.g., from 1×10⁵ to 1×10¹⁵, from 1×10⁵ to 5×10¹⁴, from 1×10⁶ to 1×10¹³, or from 1×10⁷ to 5×10¹².

In these cases, the top resistivity is greater than the bottom resistivity. Generally the bottom resistivity will be less than the top resistivity. at least 150% less, at least 200% less, at least 250% less, at least 300% less, at least 500% less or at least 1000% less.

Purity: A top purity, in some embodiments, ranges from 99.0% to 99.9%, e.g., from 99.1% to 99.9%, from 99.4% to 99.8%. A bottom purity may range from 95.0 to 99.5, e.g., from 95.5% to 99.5%, from 96% to 99%, or from 96.5% to 98.5%. Generally the bottom purity will be less than the top purity. at least 0.2%, at least 0.4%, at least 0.5% or at least 1.0%.

Theoretical density: In some cases, a top theoretical density may range from 93 to 200, e.g., from 94 to 100, from 95 to 100, from 96 to 99.5, or from 97 to 99. A bottom theoretical density may range from 93 to 100, e.g., from 94 to 99.5, from 95 to 99, or from 96 to 98. Generally the bottom theoretical density will be less than the top theoretical density. The top theoretical density may be at least 0.1% greater than the bottom theoretical density, e.g., at least 0.2%, at least 0.4%, at least 0.5% or at least 1.0%.

The theoretical density of the base plate may be similar to that of the shaft. In some cases, the theoretical density of the shaft is less than that of the base plate and/or the porosity of the shaft is greater than that of the base plate.

Grain size: In some cases, a top (maximum) grain size may range from 5 to 60 microns, e.g., from 10 to 50 microns, from 15 to 45 microns, or from 20 to 40 microns. A bottom (maximum) grain size may range from 10 to 100 microns, e.g., from 20 to 90 microns, from 25 to 85 microns, or from 30 to 80 microns. Generally the bottom (maximum) grain size will be greater than the top grain size. The top grain size may be at least 0.1% less than the bottom grain size, e.g., at least 0.2%, at least 0.4%, at least 0.5% or at least 1.0%.

Grain boundary: In some cases, a general grain boundary may range from amorphous to 10 microns, e.g., from 1 to 9 microns, from 2 to 8 microns, or from 3 to 7 microns. In some cases, the bottom grain boundary will be less than the top grain boundary. In other embodiments, the top grain boundary will be less than the bottom grain boundary.

Specific heat: In some embodiments, the base plate has a top specific heat ranging from 0.9 to 1.19 J/gK, when measured at room temperature, e.g., from 0.95 to 1.15 J/gK, or from 1.0 to 1.1 J/gK. The base plate may have a bottom specific heat ranging from 0.9 to 1.19 J/gK, when measured at room temperature, e.g., from 0.95 to 1.15 J/gK, or from 1.0 to 1.1 J/gK.

The base plate may have a top specific heat ranging from 1.8 to 2.06 J/gK when measured at 800° C., e.g., from 1.85 to 2.03 J/gK, or from 1.87 to 1.97 J/gK. The base plate may have a bottom specific heat ranging from 1.8 to 2.03 J/gK when measured at 800° C., e.g., from 1.85 to 2.03 J/gK, or from 1.87 to 1.97 J/gK.

Generally the bottom specific heat will be less than the top specific heat. The top specific heat may be at least 0.5% greater than the bottom specific heat, when measured at room temperature or at 800° C. or independent of measuring temperature, e.g., at least 1% greater, at least 2% greater, at least 5% greater, at least 5% greater, at least 10% greater or at least 20% greater.

Thermal diffusivity: In some embodiments, the base plate has a top thermal diffusivity ranging from 90 to 115 mm²/sec, when measured at room temperature, e.g., from 95 to 110 mm²/sec, or from 97 to 108 mm²/sec. The base plate may have a bottom thermal diffusivity ranging from 58 to 115 mm²/sec, when measured at room temperature, e.g., from 65 to 105 mm²/sec, or from 75 to 95 mm²/sec.

The base plate may have a top thermal diffusivity ranging from 5 to 21 mm²/sec, when measured at 800° C., e.g., from 7 to 19 mm²/sec, from 9 to 17 mm²/sec, or from 10 to 15 mm²/sec. The base plate may have a bottom thermal diffusivity ranging from 3 to 7.7 mm²/sec, when measured at 800° C., e.g., from 3.5 to 7 mm²/sec, or from 4 to 6 mm²/sec.

Generally the bottom thermal diffusivity will be less than the top specific heat. The top thermal diffusivity may be at least 0.5% greater than the bottom thermal diffusivity, when measured at room temperature or at 800° C. or independent of measuring temperature, e.g., at least 1% greater, at least 2% greater, at least 5% greater, at least 5% greater, at least 10% greater or at least 20% greater.

Effusivity: In some embodiments, the base plate has a top effusivity ranging from 22.0 to 30.02 S^{0.5}W/K/km², when measured at room temperature, e.g., 24.0 to 30.02 S^{0.5}W/K/km², from 25.0 to 29.0 S^{0.5}W/K/km², or from 26.0 to 28.0 S^{0.5}W/K/km². The base plate may have a bottom thermal effusivity ranging from 1.0 to 25.0 S^{0.5}W/K/km², when measured at room temperature, e.g., from 3.0 to 24.0 S^{0.5}W/K/km², or from 5.0 to 23.0 S^{0.5}W/K/km². In some embodiments, the base plate has a (top) effusivity greater than 22.0 S^{0.5}W/K/km², e.g., greater than 23.0 S^{0.5}W/K/km², greater than 24.0 S^{0.5}W/K/km², greater than 25.0 S^{0.5}W/K/km², greater than 27.0 S^{0.5}W/K/km², greater than 28.0 S^{0.5}W/K/km², or greater than 30.0 S^{0.5}W/K/km².

The base plate may have a top effusivity ranging from 11.0 to 16.4 S^{0.5}W/K/km², when measured at 800° C., e.g., from 12.0 to 15.0 S^{0.5}W/K/km², from 12.5 to 14.5 S^{0.5}W/K/km² or from 13.0 to 14.0 S^{0.5}W/K/km². The base plate may have a bottom thermal effusivity ranging from 0.1 to 12.0 S^{0.5}W/K/km², when measured at 800° C., e.g., from 0.5 to 11.0 S^{0.5}W/K/km², or from 1.0 to 10.0 S^{0.5}W/K/km². In some embodiments, the base plate has a (top) effusivity greater than 14.0 S^{0.5}W/K/km², e.g., greater than 15.0 S^{0.5}W/K/km², greater than 16.0 S^{0.5}W/K/km², greater than 17.0 S^{0.5}W/K/km², greater than 18.0 S^{0.5}W/K/km², greater than 19.0 S^{0.5}W/K/km², or greater than 20.0 S^{0.5}W/K/km². The effusivity improvements may also be shown at other temperatures, e.g., as shown in the Examples.

Generally the bottom effusivity will be less than the top effusivity. The top effusivity may be at least 0.5% greater than the bottom effusivity, when measured at room temperature or at 800° C. or independent of measuring temperature, e.g., at least 1% greater, at least 2% greater, at least 5% greater, at least 5% greater, at least 10% greater or at least 20% greater.

Average CTE: In some embodiments, the base plate has a top average CTE ranging from 7.0 to 9.5, e.g., from 7.2 to 9.3, from 7.5 to 9.0, or from 7.7 to 8.8. The base plate may have a bottom average CTE ranging from 7.0 to 9.5, e.g., from 7.2 to 9.3, from 7.5 to 9.0, or from 7.7 to 8.8. In some cases, the bottom average CTE will be less than the top average CTE. In other cases, the bottom average CTE will be greater than the top average CTE. The different may be at least 0.5%, when measured at room temperature or at 800° C. or independent of measuring temperature, e.g., at least 1%, at least 2%, at least 5%, at least 5%, at least 10%, or at least 20%.

In some embodiments, a top dielectric constant ranges from 1 to 20, e.g., from to 15, from 3 to 12, or from 5 to 9. A bottom dielectric constant may be similar to the top dielectric constant. In some cases, the bottom dielectric constant may be greater than the top dielectric constant. In other cases, the top dielectric constant may be greater than the bottom dielectric constant.

The base plate with the desirable performance gradients may be formed for the BeO compositions mentioned herein, which, in some cases, are modified within the compositional parameters to achieve the gradients. Also, the base plates may also demonstrate other performance features, e.g., clamping pressure, corrosion loss, temperature uniformity, etc., as disclosed herein.

### Shaft Gradient Concepts/Performance

In some embodiments, the shaft has a top thermal conductivity ranging from 146 W/mK to 218 W/mK, when measured at room temperature, e.g., from 150 W/mK to 215 W/mK, from 160 W/mK to 205 W/mK, from 165 W/mK to 200 W/mK, or from 170 W/mK to 190 W/mK. The shaft may have a bottom thermal conductivity ranging from 1 W/mK to 218 W/mK, when measured at room temperature e.g., from 50 W/mK to 218 W/mK, from 100 W/mK to 218 W/mK, from 146 W/mK to 218 W/mK, from 150 W/mK to 215 W/mK, from 160 W/mK to 205 W/mK, from 165 W/mK to 200 W/mK, or from 170 W/mK to 190 W/mK.

The shaft may have a top thermal conductivity ranging from 1 to 21, when measured at 800° C., e.g., from 3 to 20, from 5 to 15, from 7 to 13, or from 9 to 11. The shaft may have a bottom thermal conductivity ranging from 1 to 21, when measured at 800° C., e.g., from 3 to 20, from 5 to 15, from 7 to 13, or from 9 to 11.

Generally the bottom thermal conductivity will be less than the top thermal conductivity. The top thermal conductivity may be at least 6% greater than the bottom thermal conductivity, when measured at room temperature or at 800° C. or independent of measuring temperature, e.g., at least 10% greater, at least 20% greater, at least 35% greater, at least 50% greater, at least 100% greater or at least 200% greater. In some cases, the gradient may be non-linear, e.g. a step-wise function or greatest integer function. In other cases, the gradient may be linear.

### General Performance

The base plate and shaft also demonstrate superior performance numbers, generally, without the gradient taken into consideration. In some cases, the performance ranges and limits for the base plate, generally or as a whole, may be similar to the “top values” and/or “bottom values” discussed above. These are not repeated for the sake of brevity. Additional performance ranges and limits are also provided.

Thermal diffusivity: In some embodiments, the base plate has a (top) thermal diffusivity ranging from 75 to 115 mm²/sec, when measured at room temperature, e.g., from 90 to 115 mm²/sec, from 95 to 110 mm²/sec, or from 97 to 108 mm²/sec. The base plate may have a bottom thermal diffusivity ranging from 58 to 115 mm²/sec, when measured at room temperature, e.g., from 65 to 105 mm²/sec, or from 75 to 95 mm²/sec. In some embodiments, the base plate has a (top) thermal diffusivity greater than 75 mm²/sec, e.g., greater than 80 mm²/sec, greater than 85 mm²/sec, greater than 90 mm²/sec, greater than 95 mm²/sec, greater than 100 mm²/sec, or greater than 110 mm²/sec.

The base plate may have a top thermal diffusivity ranging from 5 to 21 mm²/sec, when measured at 800° C., e.g., from 7 to 19 mm²/sec, from 9 to 17 mm²/sec, or from 10 to 15 mm²/sec. The base plate may have a bottom thermal diffusivity ranging from 3 to 7.7 mm²/sec, when measured at 800° C., e.g., from 3.5 to 7 mm²/sec, or from 4 to 6 mm²/sec. In some embodiments, the base plate has a (top) thermal diffusivity greater than 5 mm²/sec, e.g., greater than 10 mm²/sec, greater than 12 mm²/sec, greater than 14 mm²/sec, greater than 15 mm²/sec, or greater than 20 mm²/sec. The thermal diffusivity improvements may also be shown at other temperatures, e.g., as shown in the Examples.

Specific heat: In some embodiments, the base plate has a top specific heat ranging from 0.7 to 1.19 J/gK, when measured at room temperature, e.g., from 0.9 to 1.19 J/gK, from 0.95 to 1.15 J/gK, or from 1.0 to 1.1 J/gK. The base plate may have a bottom specific heat ranging from 0.9 to 1.19 J/gK, when measured at room temperature, e.g., from 0.95 to 1.15 J/gK, or from 1.0 to 1.1 J/gK. In some embodiments, the base plate has a (top) specific heat greater than 0.7 J/gK, e.g., greater than 0.8 J/gK, greater than 0.9 J/gK, greater than 0.95 J/gK, or greater than 1.0 J/gK.

The base plate may have a top specific heat ranging from 1.0 to 2.06 J/gK when measured at 800° C., e.g., from 1.8 to 2.06 J/gK from 1.85 to 2.03 J/gK, or from 1.87 to 1.97 J/gK. The base plate may have a bottom specific heat ranging from 1.8 to 2.03 J/gK when measured at 800° C., e.g., from 1.85 to 2.03 J/gK, or from 1.87 to 1.97 J/gK. In some embodiments, the base plate has a (top) specific heat greater than 1.0 J/gK, e.g., greater than 1.5 J/gK, greater than 1.7 J/gK, greater than 1.8 J/gK, or greater than 1.85 J/gK. The specific heat improvements may also be shown at other temperatures, e.g., as shown in the Examples.

Thermal conductivity: In one embodiment, the second beryllium oxide composition (and the base plate) generally has a thermal conductivity less than 400 W/m-K at room temperature, e.g., less than 375 W/m-K, less than 350 W/m-K, less than 300 W/m-K, less than 275 W/m-K, less than 255 W/m-K, or less than 250 W/m-K. In terms of ranges, the second beryllium oxide composition has a thermal conductivity ranging from 125 W/m-K to 400 W/m-K, e.g., from 145 W/m-K to 350 W/m-K, from 175 W/m-K to 325 W/m-K, or from 200 W/m-K to 300 W/m-K. In some embodiments, the base plate has a (top) thermal conductivity greater than 125 W/m-K, e.g., greater than 150 W/m-K, greater than 175 W/m-K, greater than 200 W/m-K, greater than 250 W/m-K or greater than 255 W/m-K. The thermal conductivities may be measured at the top of the base plate.

In one embodiment, the second beryllium oxide composition (and the base plate) generally has a thermal conductivity less than 150 W/m-K at 800° C., e.g., less than 105 W/m-K, less than 95 W/m-K, less than 85 W/m-K, or less than 75 W/m-K. In terms of ranges, the second beryllium oxide composition has a thermal conductivity ranging from 25 to 105 W/mK, when measured at 800° C., e.g., from 35 to 95 W/mK, from 45 to 85 W/mK, or from 55 to 75 W/mK. The thermal conductivities may be measured at the top of the base plate. In some embodiments, the base plate has a (top) thermal conductivity greater than 25 W/m-K, e.g., greater than 30 W/m-K, greater than 35 W/m-K, greater than 40 W/m-K, greater than 42 W/m-K or greater than 45 W/m-K. The thermal conductivity improvements may also be shown at other temperatures, e.g., as shown in the Examples. The thermal conductivities may be measured at the top of the base plate.

Thermal conductivity of the shaft: In some embodiments, the first beryllium oxide composition (and the shaft) generally has a thermal conductivity less than 300 W/m-K at room temperature, e.g., less than 275 W/m-K, less than 250 W/m-K, less than 225 W/m-K, less than 220 W/m-K, less than 218 W/m-K, or less than 210 W/m-K. In terms of ranges, the first beryllium oxide composition has a thermal conductivity ranging from 100 W/m-K to 300 W/m-K, e.g., from 125 W/m-K to 275 W/m-K, from 125 W/m-K to 250 W/m-K, or from 140 W/m-K to 220 W/m-K. In some embodiments, the shaft has a (top) thermal conductivity greater than 125 W/m-K, e.g., greater than 150 W/m-K, greater than 175 W/m-K, greater than 200 W/m-K, greater than 250 W/m-K or greater than 255 W/m-K. The thermal conductivities may be measured at the top of the base plate. The thermal conductivities may be measured at the top of the shaft.

In some cases, the first beryllium oxide composition (and the base plate) generally has a thermal conductivity less than 25 W/m-K at 800° C., e.g., less than 23 W/m-K, less than 21 W/m-K, less than 20 W/m-K, less than 15 W/m-K, less than 10 W/m-K, or less than 5 W/m-K. In terms of ranges, the second beryllium oxide composition has a thermal conductivity ranging from 1 to 5 W/mK, when measured at 800° C., e.g., from 2 to 23 W/mK, from 4 to 21 W/mK, or from 5 to 20 W/mK. In some embodiments, the shaft has a (top) thermal conductivity greater than 25 W/m-K, e.g., greater than 30 W/m-K, greater than 35 W/m-K, greater than 40 W/m-K, greater than 42 W/m-K or greater than 45 W/m-K. The thermal conductivity improvements may also be shown at other temperatures, e.g., as shown in the Examples. The thermal conductivities may be measured at the top of the base plate.

Theoretical density of the shaft: In some embodiments, the first BeO composition (and the shaft) generally has a theoretical density ranging from 90 to 100, e.g., from 92 to 100, from 93 to 99, from 95 to 99, or from 97 to 99. In terms of lower limits, the shaft has a theoretical density greater than 90, e.g., greater than 92, greater than 93, greater than 95, or greater than 97. In terms of upper limits, the shaft has a theoretical density less than 100, e.g., less than 99.5, less than 99, less than 98.7, or less than 98. It is postulated that the desired theoretical density and porosity may result from the microstructure features provided by the first BeO composition, e.g., grain boundaries and grain size.

In some embodiments, the base plate demonstrates a bulk resistivity greater than 1×10⁴ ohm-m at 800° C., e.g., greater than greater than 5×10⁴, greater than 1×10⁵, greater than 5×10⁵, greater than 1×10⁶, greater than 5×10⁶, greater than 1×10⁷, greater than 5×10⁷, greater than 1×10⁸, greater than 5×10⁸, greater than 1×10⁹, or greater than 1×10¹⁰. This resistivity advantageously provides, at least in part, for improved clamping performance.

The inventors have found that it may be beneficial for the shaft to be less dense/more porous than the base plate. And the microstructures of the respective BeO compositions are adjusted accordingly, as disclosed herein. It is believed that such a configuration surprisingly avoid a heat sink effect (creation of cold spots) and/or avoids deforming (melting) the original plate/shaft seal.

Theoretical density of the pedestal components is an important feature. In some cases, the theoretical density (and/or porosity) affects or contributes to the thermal conductivity.

Porosity has been found to beneficially retard microfractures from spreading. In some embodiments, the base plate and/or the shaft has a porosity ranging from 0.1% to 10%, e.g., from 0.5% to 8%, from 1% to 7%, from 1% to 5%, or from 2% to 4%. In terms of upper limits, the base plate and/or the shaft may have a porosity less than 10%, e.g., less than 9%, less than 8%, less than 7%, less than 6%, less than 5%, less than 4%, less than 3%, less than 2%, or less than 1%. In terms of lower limits, the base plate and/or the shaft may have a porosity greater than 1%, e.g., greater than 2%, greater than 3%, greater than 4%, greater than 5%, greater than 6%, greater than 7%, greater than 8%, or greater than 9%.

The second BeO composition advantageously contributes to uniform temperature performance across the base plate, especially at higher temperatures. Such temperature uniformity has not been achieved using conventional, non-BeO ceramics. In some embodiments, the base plate demonstrates a temperature variance of less than ±3%, e.g., less than ±2.5%, less than ±2%, less than ±1%, or less than ±0.5%, when heated to a temperature over 700° C., e.g., over 750° C., over 800° C., or 850° C. The temperatures may be measured as is known in the art, e.g., via thermocouples, IR, or TCR devices on the top surface of the plate.

The base plate, in some cases, may demonstrate a corrosion loss of less than 0.016 wt %, e.g., less than 0.015 wt % after 200 cycles, less than 0.013 wt %, less than 0.012, less than 0.010 wt %, less than 0.008 wt %, or less than 0.005 wt %. Corrosion loss may be tested by measuring the weight of a sample before and after cycling the sample in accordance with a test protocol, e.g., 200 cycles (5.5 hrs) in NF₃ at 400° C. and 4 cycles (12 hrs) in ClF at 300° C.

The base plate, in some cases, may demonstrate a decomposition change of less than 1 wt %, e.g., less than 0.1 wt %, or less than 0.005 wt % at temperatures greater than 1600° C. Decomposition may be defined as break down into its precursor component (in some cases disassociation), e.g., a chemical change. It has been found that the disclosed base plate advantageously has an improved softening point and decomposition point. In some embodiments, the base plate has a softening point greater than 1600° C., e.g., greater than 1700° C., greater than 1750° C., greater than 1800° C., greater than 1850° C., greater than 1900° C., or greater than 2000° C. In some embodiments, the base plate has a melting point greater than 2200° C. (in nitrogen gas), e.g., greater than 2325° C., greater than 2350° C., greater than 2400° C., greater than 2450° C. Unlike conventional base plates, the disclosed base plate is capable of providing the aforementioned clamping pressure at these temperatures. Conventional base plates, e.g., aluminum nitride base plates, decompose at temperatures less than 1600° C. and will melt at temperatures less than 2200° C.

In some embodiments, the base plate has a dielectric constant less than 20, e.g., less than 17, less than 15, less than 12, less than 10, less than 8, or less than 7.

In some instances, the base plate has a surface hardness of at least 50 Rockwell, as measured on a 45N scale, e.g., least 50 Rockwell, at least 52 Rockwell, at least 55 Rockwell, at least 57 Rockwell, at least 60 Rockwell, at least 65 Rockwell, or at least 70 Rockwell.

In some embodiments, the base plate has a coefficient of thermal expansion ranging from 5 to 15 throughout the base plate, e.g., from 6 to 13, from 6.5 to 12, from 7 to 9.5, from 7.5 to 9, or from 7 to 9. In terms of upper limits, the base plate may have a coefficient of thermal expansion of greater than 5, e.g., greater than 6, greater than 6.5, greater than 7, or greater than 7.5. In terms of upper limits, the base plate may have a coefficient of thermal expansion of less than 15, e.g., less than 13, less than 12, less than 9.5, or less than 9. The coefficient of thermal expansion varies from top-to-bottom by less than 25%, e.g., less than 10%, less than 5%, less than 3%, or less than 1%.

### Pedestal Assembly Combinations

The disclosed base plate and shaft may be used in conjunction with one another. In the alternative, these components may be used in combination with other components known in the art. For example, the disclosed base plate may be used with a conventional shaft or the disclosed shaft may be employed with a conventional base plate.

In some embodiments, a pedestal assembly comprises the disclosed shaft and a base plate comprising two or more (laminated) layers and/or a co-fired ceramic material. The layers may be bonded to one another with a braze material. Examples of such base plates are those disclosed in U.S. Pat. Nos. 7,667,944 and 5,737,178, which are hereby incorporated by reference. In addition to the shaft and the base plate, these assemblies may further comprise additional hardware, e.g., heating elements, antennae, etc.

The disclosure also relates to a process for making a base plate. The base plates may be produced from a two or more grades of raw BeO powders. The BeO powders may be used to forma a precursor plate, which is then fired to yield the base plate. In one embodiment, the top surface comprises a first grade, the bottom comprises a second grade, and a middle region comprises a mixture of the first and second grades. Of course, various other numbers and combinations of raw BeO powders are considered.

In one embodiment, the process comprises the steps of: providing a first BeO powder and a third BeO powder and forming a second powder from the first and third powders. The first and second powders may comprise different grades of raw BeO. The process may further comprise forming a first (bottom) region from the first powder, forming a second (middle) region from the second powder, and forming a third (top) region from the third powder to form a base plate precursor. The forming may be achieved by distributing the respective powders in a mold in a predetermined order. The second region may be disposed between the first and third regions. Additional regions formed from additional powders may also be formed in various configurations. The process may further comprise the step of firing the base plate precursor to form the base plate.

Importantly, in some cases, once the precursor is formed, it may be co-mingled, e.g., vibrated (optionally under controlled conditions), to allow the powders to partially co-mingle or knit, which may provide for compositional gradient(s) after firing. Partial co-mingling is important to maintain the compositional gradient. In some cases, insufficient co-mingling or no co-mingling at all will result in a truly layered base plate, which may not achieve all of the benefits mentioned herein. Over-mingling may result in a homogeneous mixture of the BeO powders, without any desired compositional gradient.

The process may further comprise placing a heating element in at least one of the regions and/or crimping of terminals. The process further comprises the steps of cold forming and then firing (sintering) the base plate precursor to form the base plate.

A shaft may be made using a similar process.

Some embodiments relate to a process for making a pedestal assembly. The process comprises the steps of providing the disclosed base plate and the disclosed shaft, and connecting the shaft to the base plate.

### EXAMPLES

### Examples 1-4 and Comparative Examples A-C

Examples 1-4 utilized coupons prepared from various BeO grades and Comparative Examples A-C utilized coupons prepared from various AlN grades, as shown in Table 1. The coupons were machined from larger ceramic block pieces using standard abrasive diamond grinding and cleaning practices.

TABLE 1
Coupon Composition*

| Ex./Comp. Ex. | Ceramic | Composition (wt %) | Purity, % |
|---|---|---|---|
| Ex. 1 | BeO | BeO, Mg₂O₈Si₃ (<0.5), | >99.5 |
| | Thermalox 995 | S (<0.5) | |
| Ex. 2 | BeO HIP | BeO, Li₂O (<1), S(<1), | 85-99.5 |
| | | SiO₂ (<1), Mg₂O₈Si₃ (<1) | |
| Ex. 3 | BeO VHP | BeO, Li₂O (<1), S(<1), | 85-99.5 |
| | | SiO₂ (<1), Mg₂O₈Si₃ (<1) | |
| Ex. 4 | BeO VHP-HT | BeO, Li₂O (<1), S(<1), | >99.5 |
| | | SiO₂ (<1), Mg₂O₈Si₃ (<1) | |
| Comp. Ex. A | AlN 1 | AlN, Y₂O₃, organics | 88-97.1 |
| Comp. Ex. B | AlN 2 | AlN, Y₂O₃, organics | 88-97.1 |
| Comp. Ex. C | AlN 3 | AlN, Y₂O₃, organics, | 88-97.1 |
| | | CaO Li₂O MgO, YF₃ | |

*other components of the composition may be present in trace amounts

The dimensions of the coupons conformed with various ASTM standards, as shown in Table 2.

TABLE 2
Coupon Dimension Standards

| Standard | Measurement |
|---|---|
| ASTM D-150 (D-116) | Dielectric; |
| ASTM D-149 (D-116) | AC Loss Permittivity |
| ASTM D-357 (D-116) | |
| ENG 1362 | Thermal Diffusivity |
| ASTM C 51 | Specific Heat |
| ASTM E1269 | |

Examples 1-4 and Comparative Examples A-C were tested for thermal diffusivity. Thermal diffusivity was measured using a NETZSCH LFA 467 HT Hyperflash, in accordance with ASTM E1461-13 (2013). Half rise time was greater than 10 ms. The specimens were sputter coated with 0.2 μm of gold and spray coated with 5 μm of graphite. Specific heat was measured using a Netzsch DSC 404 F1 Pegasus Differential Scanning calorimeter, in accordance with ASTM E1269 (2013). Values at 25° C. are extrapolated.

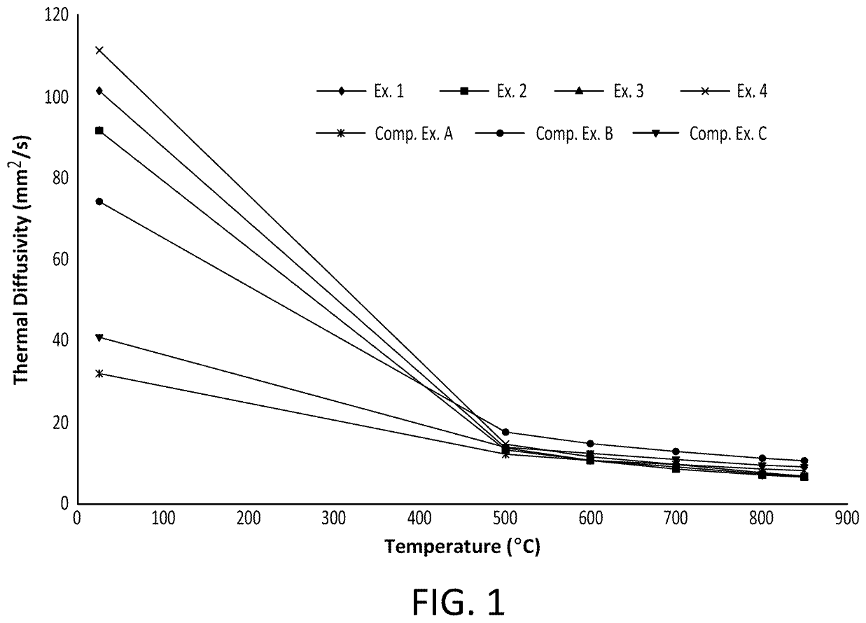

Thermal diffusivity results are shown in FIG. 1. As shown in FIG. 1, BeO Examples 1-4 beneficially demonstrated significantly higher thermal diffusivity than AlN Comparative Examples A-C at temperatures up to 500° C. At temperatures over 500° C., Examples 1-4 also showed higher thermal diffusivity. The differences were not was not as great, but were still significant—even slight differences contribute to notable performance improvements.

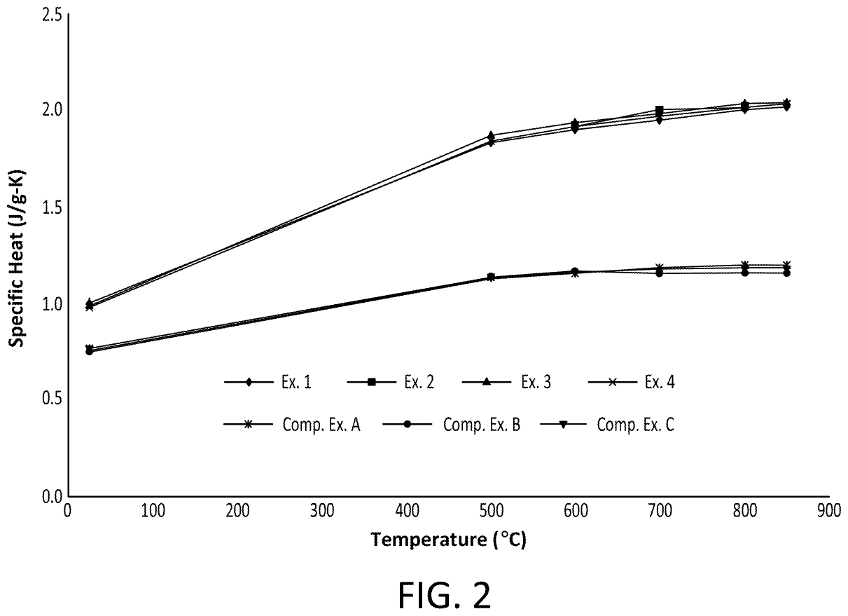

Examples 1-4 and Comparative Examples A-C were tested for specific heat. Specific heat is the amount of energy required to change the temperature of a body. Specific heat results are shown in FIG. 2. As shown in FIG. 2, BeO Examples 1-4 beneficially showed higher specific heat values than AlN Comparative Examples A-C. In fact, all of Examples 1-4 show higher results than all of Comparative Examples A-C over the temperature range. Advantageously, Examples 1-4 reacted more slowly to power variation (lower hysteresis), especially once operating temperature was reached.

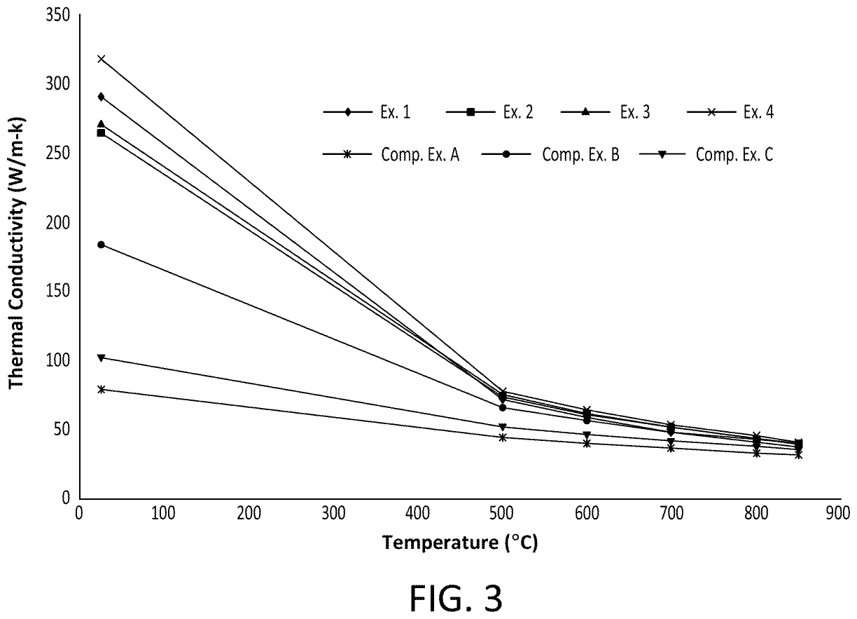

Examples 1-4 and Comparative Examples A-C were tested for thermal conductivity, the results are shown in FIG. 3. Fourier's heat equation was applied to calculate thermal conductivity from the specific heat and thermal diffusivity and density. Thermal conductivity governs the steady state heat variation of a body. As shown, BeO Examples 1-4 advantageously reach a steady state temperature faster than AlN Comparative Examples A-C at temperatures up to 500° C. At temperatures over 500° C., Examples 1-4 also showed higher thermal conductivity. The differences were not was not as great, but were still significant. And as was the case with thermal diffusivity, even slight differences contribute to notable performance improvements.

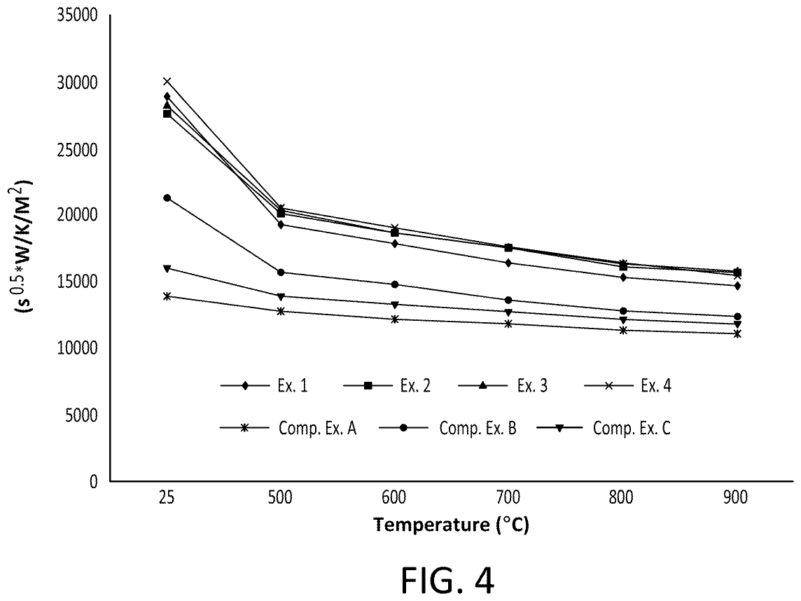

Examples 1-4 and Comparative Examples A-C were measured for effusivity, the results are shown in FIG. 4. Effusivity was calculated from other thermal values. Effusivity controls the temperature at the point and moment of contact of two bodies, e.g. between the heating element and BeO, and between BeO and backside He gas and Si wafer. As shown, BeO Examples 1-4 beneficially show higher effusivity values than AlN Comparative Examples A-C across the temperature range. All of Examples 1-4 show higher effusivity values than all of Comparative Examples A-C over the temperature range. Examples 1-4 remained at a more stable temperature with less temperature drop upon contact with the backside gas and wafer, with less thermal stress history as compared to Comparative Examples A-C.

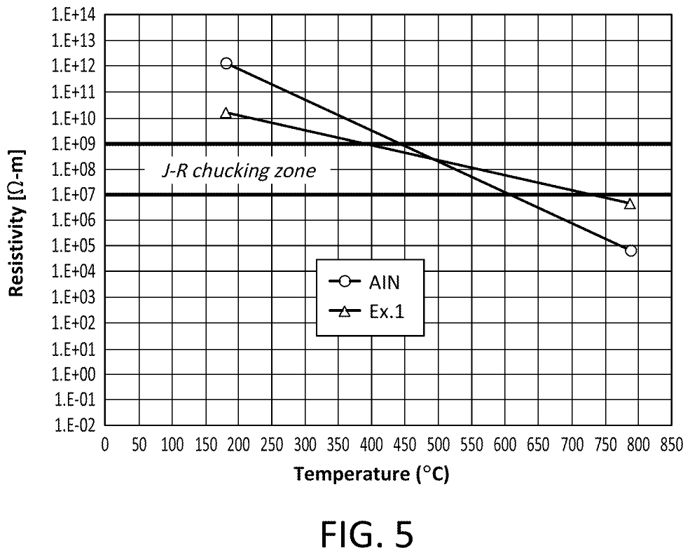

Examples 1-4 and Comparative Examples A-C were measured for bulk resistivity, the results are shown in FIG. 5. Bulk resistivity was measured in accordance with ASTM D257/ASTM D1829 procedure A using a Keithley 237 HV Source. Bulk resistivity relates to clamping (at higher temperatures). At elevated temperatures higher bulk resistivities are beneficial. J-R clamping is generally electrostatically active in the range of 1×10⁷ to 1×10⁹ m (at 400 V to 600 V). FIG. 5 shows the resistivity slope for the highest values of Examples 1-4 and the highest values of Comparative Examples A-C. The slope of the curve relates to time in the “chucking/clamping zone” of 1×10⁷ to 1×10⁹ Ω-m. As shown in FIG. 5, Examples 1-4 surprisingly have a much flatter curve and spend much more time in the chucking/clamping zone. This is demonstrative of improved clamping performance and provides for the superior clamping pressure performance disclosed herein, e.g., clamping pressure of at least 133 kPa.

### Examples 5 and 6

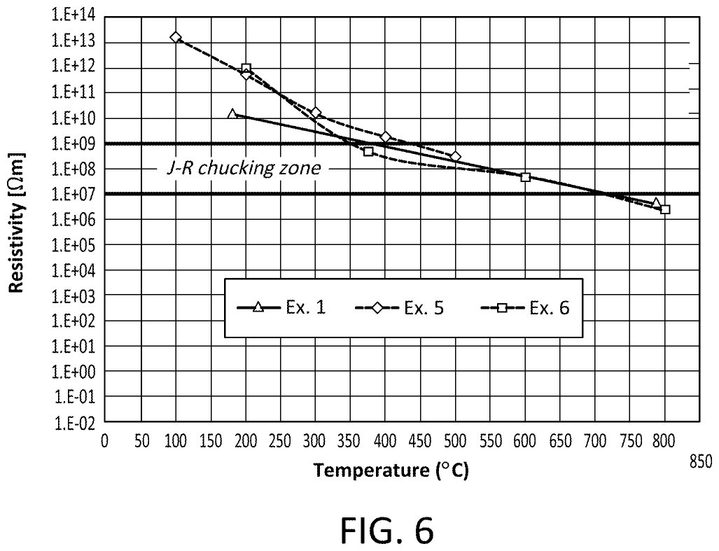

Additional samples of BeO materials were tested for bulk resistivity in a similar manner. The compositions of the BeO materials is shown in Table 3. Examples 5 and 6 are prepared from substantially similar mixtures of ceramic powder. Examples 5 and 6 were measured at different facilities at different times. As shown in FIG. 6, the curves for Examples 1, 5, and 6 are quite similar, and well within the expected typical batch-to-batch variations, especially in the chucking/clamping range.

TABLE 3
BeO Compositions*

| Ex./Comp. Ex. | Ceramic | Composition (wt %) | Purity, % |
|---|---|---|---|
| Ex. 1 | BeO | BeO, Mg₂O₈Si₃ (<0.5), | >99.5 |
| | Thermalox 995 | S (<0.5) | |
| Ex. 5 | BeO | BeO, Mg₂O₈Si₃ (<0.5), | >99.5 |
| | Thermalox 995 | S (<0.5) | |
| Ex. 6 | BeO | BeO, Mg₂O₈Si3 (<0.5), | >99.5 |
| | Thermalox 995 | S (<0.5) | |

*other components of the composition may be present in trace amounts

The results are shown in FIG. 6. As shown, Examples 1, 5, and 6 perform particularly well, especially at higher temperatures.

### Example 7 and Comparative Example D

Example 7 utilized a coupon comprising a BeO composition comprising BeO (>99.5% purity). Comparative Example D utilized a coupon comprising an AlN composition. Example 7 and Comparative Example D were tested for corrosion resistance by measuring initial weight, treatment, then measuring final weight. Treatment was 200 cycles (5.5 hours) in NF₃ at 400° C. and 4 cycles (12 hours) in ClF at 300° C. Example 7 surprisingly demonstrated an average percentage loss of only 0.007 wt %, while Comparative Example D demonstrated an average percentage of 0.016—greater than twice that of Example 7 (the weight loss of Example 7 was 56% less than the weight loss of Comparative Example D.

### Example 8

A base plate of Example 8 was prepared as follows. Ready to press (RTP) powder (high TC powder) containing a high thermal conductivity grade of BeO and optional binders, lubricants, sintering aids was prepared. A similar powder was prepared using a lower thermal conductivity grade BeO (low TC powder). Quantities of high TC powder and low TC powder were blended to product a medium TC powder.

A platen shaped elastomer/graphite cavity mold was filled at the bottom third volume with high TC powder. A metallic heating element of niobium in the form of foil or deposit or film or wire, was placed within the powder bed. Then the medium TC powder was added to the middle third volume. A metallic ground plane or radio frequency antenna or electrode of niobium was placed within the powder bed. Then the top third volume was filled with low TC powders.

Electrical connecting posts and terminations were inserted through every powder layer and connected to the metallic elements embedded within. The mold was sealed and pressurized at room temperature to compact/densify the powder. The compacted powder shape was held together with a temporary organic or inorganic binder was green machined to a near net shaped object. The object was then sintered in a furnace to induce densification. The object was machined to finished size requirements, thus resulting in the final base plate, which had the various property gradients disclosed herein. Power and or other connection was applied to the electrical connection posts to operate the device for heating and electrostatic chucking.

The base plate was heated in a test chamber so that the surface of a silicon wafer resting on the base plate reached a temperature of 800° C. (the temperature at which semiconductor production chamber are preferably operated). Surprisingly, the base plate performed very well at high temperatures. For example, the base plate did not crack and demonstrated bulk resistivity performance similar to the values discussed above (FIG. 5), e.g., resistivity. These unexpected resistivity values correlate to superior clamping performance at high temperatures, e.g., electrostatic chucking/clamping is maintained (at high temperatures). Such performance has not been achieved with conventional base plate materials, e.g., AlN.

### Embodiments

The following embodiment, among others, are disclosed.

Embodiment 1: A pedestal assembly comprising: a shaft containing a first beryllium oxide composition containing beryllium oxide and fluorine/fluoride ion; and a base plate containing a second beryllium oxide composition containing at least 95 wt % beryllium oxide and optionally fluorine/fluoride ion; wherein the base plate demonstrates a clamping pressure of at least 133 kPa.

Embodiment 2: an embodiment of embodiment 1, wherein the first beryllium oxide composition comprises from 1 ppb to 1000 ppm fluorine/fluoride ion.

Embodiment 3: an embodiment of embodiment 1 or 2, wherein the first beryllium oxide composition comprises more fluorine/fluoride ion than the second beryllium oxide composition.

Embodiment 4: an embodiment of any of embodiments 1-3, wherein the first beryllium oxide composition is processed to achieve the fluorine/fluoride ion concentration.

Embodiment 5: an embodiment of any of embodiments 1-4, wherein the first beryllium oxide composition further comprises less than 50 wt % magnesium oxide and less than 50 wt % ppm silicon dioxide.

Embodiment 6: an embodiment of any of embodiments 1-5, wherein the first beryllium oxide composition further comprises: from 1 ppb to 50 wt % ppm alumina; from 1 ppb to 10000 ppm sulfites; and/or from 1 ppb to 1 wt % ppm boron, barium, sulfur, or lithium, or combinations thereof including oxides, alloys, composites, or allotropes, or combinations thereof.

Embodiment 7: an embodiment of any of embodiments 1-6, wherein the first beryllium oxide composition has average grain boundaries greater than 0.1 micron.

Embodiment 8: an embodiment of any of embodiments 1-7, wherein the first beryllium oxide composition has an average grain size less than 100 microns.

Embodiment 9: an embodiment of any of embodiments 1-8, wherein the second beryllium oxide composition comprises from 1 ppb to 10 wt % ppm magnesium oxide and from 1 ppb to 10 wt % ppm silicon dioxide.

Embodiment 10: an embodiment of any of embodiments 1-9, wherein the second beryllium oxide composition comprises from 1 ppb to 10 wt % ppm magnesium trisilicate.

Embodiment 11: an embodiment of any of embodiments 1-10, wherein the first beryllium oxide composition comprises more magnesium oxide and/or magnesium trisilicate than the second beryllium composition.

Embodiment 12: an embodiment of any of embodiments 1-11, wherein the second beryllium oxide composition comprises from 1 ppb to 1 wt % lithia.

Embodiment 13: an embodiment of any of embodiments 1-12, wherein first beryllium oxide composition comprises less than 75 wt % aluminum nitride and/or the second beryllium oxide composition comprise less than 5 wt % aluminum nitride.

Embodiment 14: an embodiment of any of embodiments 1-13, wherein the first beryllium oxide composition has a conductivity less than 300 W/m-K at room temperature.

Embodiment 15: an embodiment of any of embodiments 1-14, wherein the second beryllium oxide composition has a conductivity less than 400 W/m-K at room temperature.

Embodiment 16: an embodiment of any of embodiments 1-15, wherein the first beryllium oxide composition has a theoretical density ranging from 90% to 100%.

Embodiment 17: an embodiment of any of embodiments 1-16, wherein the base plate demonstrates a temperature variance of less than ±3%, when heated to a temperature over 700° C.

Embodiment 18: an embodiment of any of embodiments 1-17, wherein the base plate demonstrates a bulk resistivity greater than 1×10⁴ ohm-m at 800° C.

Embodiment 19: an embodiment of any of embodiments 1-18, wherein the base plate demonstrates a corrosion loss of less than 0.016 wt %.

Embodiment 20: an embodiment of any of embodiments 1-19, wherein the base plate has a dielectric constant less than 20.

Embodiment 21: an embodiment of any of embodiments 1-20, wherein the base plate has a surface hardness of at least 50 Rockwell on a 45N scale.

Embodiment 22: an embodiment of any of embodiments 1-21, wherein the base plate has a coefficient of thermal expansion ranging from 5 to 15 throughout the base plate.

Embodiment 23: an embodiment of any of embodiments 1-22, further comprising a heating element encapsulated in the base plate.

Embodiment 24: an embodiment of any of embodiments 1-23, wherein a minimum transverse measurement across the base plate is at least 100 mm.

Embodiment 25: an embodiment of any of embodiments 1-24, wherein the base plate has a flatness with a camber of less than 50 microns across a distance of 300 mm.

Embodiment 26: an embodiment of any of embodiments 1-25, wherein base plate further comprises a mesa, optionally having a height greater than 1 micron.

Embodiment 27: an embodiment of any of embodiments 1-26, wherein the shaft comprises a stub portion having a similar coefficient of thermal expansion.

Embodiment 28: an embodiment of any of embodiments 1-27, wherein the base plate contains fewer than 2 layer laminations.

Embodiment 29: an embodiment of any of embodiments 1-28, wherein the base plate contains no discrete layers.

Embodiment 30: A base plate having a top and a bottom and comprising a beryllium oxide composition, containing at least 95 wt % beryllium oxide and optionally fluorine/fluoride ion; wherein the base plate demonstrates a clamping pressure of at least 133 kPa at a temperature of at least 600° C. and, wherein the base plate demonstrates a decomposition change of less than 1 wt % at temperatures greater than 1600° C.

Embodiment 31: an embodiment of embodiment 30, wherein the base plate demonstrates a temperature variance of less than ±3%, when heated to a temperature over 700° C.; and/or a bulk resistivity greater than 1×10⁸; and/or corrosion loss of less than 0.016 wt %; and/or a dielectric constant less than 20; and/or a surface hardness of at least 50 Rockwell on a 45N scale; and/or a coefficient of thermal expansion ranging from 5 to 15 throughout the base plate.

Embodiment 32: an embodiment of embodiment 30 or 31, wherein a coefficient of thermal expansion varies from top-to-bottom by less than 25%.

Embodiment 33: an embodiment of any of embodiments 30-32, wherein the base plate demonstrates a cleaning cycle time less than 2 hours and a temperature variance of less than ±3%.

Embodiment 34: an embodiment of any of embodiments 30-33, wherein the beryllium oxide composition comprises from 1 ppb to 10 wt % ppm magnesium oxide and from 1 ppb to 10 wt % ppm silicon dioxide.

Embodiment 35: an embodiment of any of embodiments 30-34, wherein the beryllium oxide composition comprises from 1 ppb to 10 wt % ppm magnesium trisilicate.

Embodiment 36: an embodiment of any of embodiments 30-35, wherein the base plate contains no discrete layers.

Embodiment 37: an embodiment of any of embodiments 30-36, wherein the base plate has: a decreasing top-to-bottom thermal conductivity gradient; and/or a decreasing top-to-bottom resistivity gradient; and/or a decreasing top-to-bottom purity gradient; and/or a decreasing top-to-bottom theoretical density gradient; and/or an increasing top-to-bottom dielectric constant gradient.

Embodiment 38: an embodiment of any of embodiments 30-37, further comprising a heating element, optionally a coiled and/or crimped heating element.

Embodiment 39: an embodiment of any of embodiments 30-38, further comprising an antenna.

Embodiment 40: an embodiment of any of embodiments 30-39, wherein the heating element and/or the antenna comprise niobium and/or platinum.

Embodiment 41: A base plate having a top and a bottom and comprising a beryllium oxide composition, wherein the base plate has: a decreasing top-to-bottom thermal conductivity gradient; and/or a decreasing top-to-bottom resistivity gradient; and/or a decreasing top-to-bottom purity gradient; and/or a decreasing top-to-bottom theoretical density gradient; and/or an increasing top-to-bottom dielectric constant gradient.

Embodiment 42: an embodiment of embodiment 41, wherein a top thermal conductivity ranges from 125 to 400 W/mK and a bottom thermal conductivity ranges from 146 W/mK to 218 W/mK, when measured at room temperature; and/or a top thermal conductivity ranges from 25 W/mK to 105 W/mK and a bottom thermal conductivity ranges from 1 W/mK to 21 W/mK, when measured at 800° C.

Embodiment 43: an embodiment of embodiment 41 or 42, the top thermal conductivity is at least 6% greater than the bottom thermal conductivity, when measured at room temperature; and/or the top thermal conductivity is at least 6% greater than the bottom thermal conductivity when measured at 800° C.

Embodiment 44: an embodiment of any of embodiments 41-43, wherein a top purity ranges from 99.0 to 99.9 and a bottom purity ranges from 95.0 to 99.5.

Embodiment 45: an embodiment of any of embodiments 41-44, wherein the top purity is at least 0.4% greater than the bottom purity.

Embodiment 46: an embodiment of any of embodiments 41-45, wherein a top theoretical density ranges from 93% to 100% and a bottom theoretical density ranges from 93% to 100%.

Embodiment 47: an embodiment of any of embodiments 41-46, wherein the top theoretical density is at least 0.5% greater than the bottom theoretical density.

Embodiment 48: an embodiment of any of embodiments 41-47, wherein a top dielectric constant ranges from 1 to 20 and a bottom dielectric constant ranges from 1 to 20.

Embodiment 49: an embodiment of any of embodiments 41-48, wherein the base plate contains no discrete layers.

Embodiment 50: an embodiment of any of embodiments 41-49, wherein the base plate demonstrates a clamping pressure of at least 133 KPa.

Embodiment 51: an embodiment of any of embodiments 41-50, wherein the base plate demonstrates a temperature variance of less than ±3%, when heated to a temperature over 700° C.

Embodiment 52: an embodiment of any of embodiments 41-51, wherein the base plate demonstrates a corrosion loss of less than 0.016 wt %.

Embodiment 53: A shaft for a pedestal assembly comprising a beryllium oxide composition containing beryllium oxide and fluorine/fluoride ion; wherein the beryllium oxide composition has average grain boundaries greater than 0.1 micron or an amorphous grain structure.

Embodiment 54: an embodiment of embodiment 53, wherein the beryllium oxide composition has an average grain size less than 100 microns.

Embodiment 55: an embodiment of embodiment 53 or 54, wherein beryllium oxide composition comprises less than 75 wt % aluminum nitride.

Embodiment 56: an embodiment of any of embodiments 53-55, wherein first beryllium oxide composition has a thermal conductivity less than 300 W/m-K at room temperature.

Embodiment 57: an embodiment of any of embodiments 53-56, wherein the beryllium oxide composition has a theoretical density ranging from 90 to 100.

Embodiment 58: an embodiment of any of embodiments 53-57, wherein: a top thermal conductivity ranges from 146 W/mK to 218 W/mK and a bottom thermal conductivity ranges from 1 W/mK to 218 W/mK, when measured at room temperature; and/or a top thermal conductivity ranges from 1 W/mK to 21 W/mK and a bottom thermal conductivity ranges from 1 W/mK to 21 W/mK, when measured at 800° C.

Embodiment 59: an embodiment of any of embodiments 53-58, wherein the top theoretical density is at least 0.5% greater than the bottom theoretical density.

Embodiment 60: an embodiment of any of embodiments 53-59, wherein the first beryllium oxide composition comprises from 1 ppb to 1000 ppm fluorine/fluoride ion.

Embodiment 61: an embodiment of any of embodiments 53-60, wherein the first beryllium oxide composition further comprises less than 50 wt % magnesium oxide and less than 50 wt % ppm silicon dioxide.

Embodiment 62: an embodiment of any of embodiments 53-61, wherein the first beryllium oxide composition further comprises: from 1 ppb to 50 wt % ppm alumina; from 1 ppb to 10000 ppm sulfites; and/or from 1 ppb to 1 wt % ppm boron, barium, sulfur, or lithium, or combinations thereof including oxides, alloys, composites, or allotropes, or combinations thereof.

Embodiment 63: a pedestal assembly comprising: the shaft of any of embodiments 53-62; and a base plate containing multiple layers bonded with one another optionally with a braze material; and an optional printed heating element.

Embodiment 64: a base plate having a top and a bottom and comprising a ceramic composition, wherein the base plate demonstrates: a clamping pressure of at least 133 kPa; a temperature variance of less than ±3%, when heated to a temperature over 700° C.; and/or a bulk resistivity greater than 1×10⁸ at 800° C.; and/or a corrosion loss of less than 0.016 wt %; and/or a dielectric constant less than 20; and/or a surface hardness of at least 50 Rockwell on a 45N scale; and/or a coefficient of thermal expansion ranging from 5 to 15 throughout the base plate.

Embodiment 65: a process for making a base plate, the process comprising the steps of: providing a first BeO powder and a third BeO powder; forming a second powder from the first and third powders; forming a first (bottom) region from the first powder; forming a second (middle) region from the second powder; forming a third (top) region from the third powder to form a base plate precursor, wherein the second region is disposed between the first and third regions; and firing the base plate precursor to form the base plate.

Embodiment 66: an embodiment of embodiments 65, wherein the first and third (and second) powders comprise different grades of raw BeO.

Embodiment 67: an embodiment of embodiment 65 or 66, further comprising placing a heating element in one of the regions and/or crimping of terminals.

Embodiment 68: an embodiment of any of embodiments 65-67, further comprising co-mingling the base plate precursor to knit the powders.

Embodiment 69: an embodiment of any of embodiments 65-68, further comprising the step of cold forming the base plate precursor.

Embodiment 70: a process for making a pedestal shaft, comprising processing a beryllium oxide composition to achieve a fluorine/fluoride ion concentration ranging from 1 ppb to 1000 ppm fluorine/fluoride ion.

Embodiment 71: a process for cleaning a contaminated pedestal assembly, comprising: providing the pedestal assembly and a wafer with the wafer disposed atop the pedestal assembly; heating the wafer to a temperature above 600° C.; cooling the wafer by less than 100° C. to a cooled temperature (or no cooling at all); cleaning the plate at the cooled temperature; optionally re-heating the wafer to 600° C.; wherein a cleaning cycle time from the cooling step to the reheating step is less than 2 hours.

Embodiment 72: an embodiment of embodiment 71, wherein the cleaning cycle time ranges from 0 to 10 minutes.

Embodiment 73: a base plate having a top and a bottom and comprising a beryllium oxide composition, containing at least 95 wt % beryllium oxide and optionally fluorine/fluoride ion; wherein the base plate demonstrates a clamping pressure of at least 133 kPa at a temperature of at least 600° C. and a bulk resistivity greater than 1×10⁵ ohm-m at 800° C.

Embodiment 74: an embodiment of embodiment 73, wherein the base plate demonstrates: a temperature variance of less than ±3%, when heated to a temperature over 700° C.; and/or a decomposition change of less than 1 wt % at temperatures greater than 1600° C.; and/or a dielectric constant less than 20; and/or a surface hardness of at least 50 Rockwell on a 45N scale; and/or a coefficient of thermal expansion ranging from 5 to 15 throughout the base plate.

Embodiment 75: an embodiment of embodiment 73 or 74, wherein the base plate comprises a beryllium oxide composition comprising from 1 ppm to 5 wt % ppm magnesium oxide and from 1 ppm to 5 wt % silicon dioxide and from 1 ppm to less than 5 wt % ppm magnesium trisilicate.

Embodiment 76: an embodiment of any of embodiments 73-75, wherein a coefficient of thermal expansion varies from top-to-bottom by less than 25%.

Embodiment 77: an embodiment of any of embodiments 73-76, wherein the base plate demonstrates a corrosion loss of less than 0.016 wt %.

Embodiment 78: an embodiment of any of embodiments 73-77, wherein the base plate demonstrates a cleaning cycle time less than 2 hours and a temperature variance of less than ±3%.

Embodiment 79: an embodiment of any of embodiments 73-78, wherein the base plate contains no discrete layers.

Embodiment 80: an embodiment of any of embodiments 73-79, wherein the base plate demonstrates a temperature variance of less than ±3%, when heated to a temperature over 700° C.

Embodiment 81: an embodiment of any of embodiments 73-80, wherein the base plate has: a decreasing top-to-bottom thermal conductivity gradient; a decreasing top-to-bottom resistivity gradient; and a decreasing top-to-bottom purity gradient.

Embodiment 82: an embodiment of any of embodiments 73-81, wherein the top purity is at least 0.4% greater than the bottom purity.

Embodiment 83: a pedestal assembly comprising: a shaft containing a first beryllium oxide composition containing beryllium oxide and fluorine/fluoride ion; and a base plate containing a second beryllium oxide composition containing at least 95 wt % beryllium oxide; wherein the base plate demonstrates a clamping pressure of at least 133 kPa at a temperature of at least 600° C. and a bulk resistivity greater than 1×10⁵ ohm-m at 800° C.

Embodiment 84: an embodiment of embodiment 83, wherein the first beryllium oxide composition has average grain boundaries greater than 0.1 micron.

Embodiment 85: an embodiment of embodiment 83 or 84, wherein the first beryllium oxide composition has an average grain size less than 100 microns.

Embodiment 86: an embodiment of any of embodiments 83-85, wherein the first beryllium oxide composition comprises from 10 ppb to 800 ppm fluorine/fluoride ion.

Embodiment 87: an embodiment of any of embodiments 83-86, wherein the first beryllium oxide composition comprises more fluorine/fluoride ion than the second beryllium oxide composition.

Embodiment 88: an embodiment of any of embodiments 83-87, wherein the first beryllium oxide composition further comprises: from 1 ppb to 50 wt % ppm alumina; from 1 ppb to 10000 ppm sulfites; and/or from 1 ppb to 1 wt % ppm boron, barium, sulfur, or lithium, or combinations thereof including oxides, alloys, composites, or allotropes, or combinations thereof.

Embodiment 89: an embodiment of any of embodiments 83-88, wherein first beryllium oxide composition comprises less than 75 wt % aluminum nitride and the second beryllium oxide composition comprises less than 5 wt % aluminum nitride.

Embodiment 90: a shaft for a pedestal assembly comprising a beryllium oxide composition containing beryllium oxide and from 10 ppb to 800 ppm fluorine/fluoride ion; wherein the beryllium oxide composition has average grain boundaries greater than 0.1 micron or an amorphous grain structure and an average grain size less than 100 microns.

Embodiment 91, a process for making a base plate, the process comprising the steps of: providing a first BeO powder and a third BeO powder; forming a second powder from the first and third powders; forming a first (bottom) region from the first powder; forming a second (middle) region from the second powder; forming a third (top) region from the third powder to form a base plate precursor, wherein the second region is disposed between the first and third regions; and firing the base plate precursor to form the base plate.

Embodiment 92, an embodiment of embodiment 91, wherein the first and third, and optionally second, powders comprise different grades of raw BeO.

While the invention has been described in detail, modifications within the spirit and scope of the invention will be readily apparent to those of skill in the art. In view of the foregoing discussion, relevant knowledge in the art and references discussed above in connection with the Background and Detailed Description, the disclosures of which are all incorporated herein by reference. In addition, it should be understood that aspects of the invention and portions of various embodiments and various features recited below and/or in the appended claims may be combined or interchanged either in whole or in part. In the foregoing descriptions of the various embodiments, those embodiments which refer to another embodiment may be appropriately combined with other embodiments as will be appreciated by one of skill in the art. Furthermore, those of ordinary skill in the art will appreciate that the foregoing description is by way of example only, and is not intended to limit.

1. A base plate having a top and a bottom and comprising a beryllium oxide composition, containing at least 95 wt % beryllium oxide and optionally fluorine/fluoride ion;
wherein the base plate demonstrates a clamping pressure of at least 133 kPa at a temperature of at least 600° C. and a bulk resistivity greater than 1×10⁵ ohm-m at 800° C.

2. The base plate of claim 1, wherein the base plate comprises a beryllium oxide composition comprising from 1 ppm to 5 wt % ppm magnesium oxide and from 1 ppm to 5 wt % silicon dioxide and from 1 ppm to less than 5 wt % ppm magnesium trisilicate.

3. The base plate of claim 1, wherein the base plate demonstrates:
a temperature variance of less than ±3%, when heated to a temperature over 700° C.; and/or
a decomposition change of less than 1 wt % at temperatures greater than 1600° C.; and/or
a dielectric constant less than 20; and/or
a surface hardness of at least 50 Rockwell on a 45N scale; and/or
a coefficient of thermal expansion ranging from 5 to 15 throughout the base plate.

4. The base plate of claim 1, wherein a coefficient of thermal expansion varies from top-to-bottom by less than 25%.

5. The base plate of claim 1, wherein the base plate demonstrates a corrosion loss of less than 0.016 wt %.

6. The base plate of claim 1, wherein the base plate demonstrates a cleaning cycle time less than 2 hours and a temperature variance of less than ±3%.

7. The base plate of claim 1, wherein the base plate contains no discrete layers.

8. The base plate of claim 1, wherein the base plate demonstrates a temperature variance of less than ±3%, when heated to a temperature over 700° C.

9. The base plate of claim 1, wherein the base plate has:
a decreasing top-to-bottom thermal conductivity gradient;
a decreasing top-to-bottom resistivity gradient; and
a decreasing top-to-bottom purity gradient.

10. The base plate of claim 1, wherein the top purity is at least 0.4% greater than the bottom purity.

11. A pedestal assembly comprising:
a shaft containing a first beryllium oxide composition containing beryllium oxide and fluorine/fluoride ion; and
a base plate containing a second beryllium oxide composition containing at least 95 wt % beryllium oxide;
wherein the base plate demonstrates a clamping pressure of at least 133 kPa at a temperature of at least 600° C. and a bulk resistivity greater than 1×10⁵ ohm-m at 800° C.

12. The assembly of claim 11, wherein the first beryllium oxide composition has average grain boundaries greater than 0.1 micron.

13. The assembly of claim 11, wherein the first beryllium oxide composition has an average grain size less than 100 microns.

14. The assembly of claim 11, wherein the first beryllium oxide composition comprises from 10 ppb to 800 ppm fluorine/fluoride ion.

15. The assembly of claim 11, wherein the first beryllium oxide composition comprises more fluorine/fluoride ion than the second beryllium oxide composition.

16. The assembly of claim 11, wherein the first beryllium oxide composition further comprises:
from 1 ppb to 50 wt % ppm alumina;
from 1 ppb to 10000 ppm sulfites; and/or
from 1 ppb to 1 wt % ppm boron, barium, sulfur, or lithium, or combinations thereof including oxides, alloys, composites, or allotropes, or combinations thereof.

17. The assembly of claim 11, wherein first beryllium oxide composition comprises less than 75 wt % aluminum nitride and the second beryllium oxide composition comprises less than 5 wt % aluminum nitride.

18. A shaft for a pedestal assembly comprising a beryllium oxide composition containing beryllium oxide and from 10 ppb to 800 ppm fluorine/fluoride ion;
wherein the beryllium oxide composition has average grain boundaries greater than 0.1 micron or an amorphous grain structure and an average grain size less than 100 microns.

19. A process for making a base plate, the process comprising the steps of:
providing a first BeO powder and a third BeO powder;
forming a second powder from the first and third powders;
forming a first (bottom) region from the first powder;
forming a second (middle) region from the second powder;
forming a third (top) region from the third powder to form a base plate precursor, wherein the second region is disposed between the first and third regions; and
firing the base plate precursor to form the base plate.

20. The process of claim 19, wherein the first and third, and optionally second, powders comprise different grades of raw BeO.
